(19) United States
(12) Patent Application Publication
(10) Pub. No.: US 2025/0391490 A1
(43) Pub. Date: Dec. 25, 2025

(54) STORAGE DEVICE INCLUDING MEMORY DEVICE, OPERATION METHOD OF STORAGE DEVICE, AND OPERATION METHOD OF MEMORY DEVICE

(71) Applicant: SAMSUNG ELECTRONICS CO., LTD., Suwon-si (KR)

(72) Inventors: Taeyun Lee, Suwon-si (KR); Sang-Won Park, Suwon-si (KR); Se Hwan Park, Suwon-si (KR); Il Han Park, Suwon-si (KR); Jung Lee, Suwon-si (KR)

(21) Appl. No.: 19/221,171

(22) Filed: May 28, 2025

(30) Foreign Application Priority Data
Jun. 19, 2024 (KR) 10-2024-0079753
Aug. 13, 2024 (KR) 10-2024-0107970

(51) Int. Cl. G11C 29/52; G11C 16/08; G11C 16/10; G11C 16/24; G11C 16/34

(52) U.S. Cl. CPC G11C 29/52; G11C 16/08; G11C 16/102; G11C 16/24; G11C 16/3404

(57) ABSTRACT

Disclosed are storage devices and operation methods thereof. A method includes performing a normal read operation on a memory block of the memory device to read first user data, performing an error correction operation on the first user data, and performing a special read operation on the memory block to read second user data when an error of the first user data fails to be corrected. The memory block includes cell strings, and the cell strings share ground selection lines. In the normal read operation, the memory device applies a first voltage to at least one ground selection line of the ground selection lines and applies a second voltage higher than the first voltage to remaining ground selection lines. In the special read operation, the memory device applies the second voltage or a third voltage higher than the second voltage to the ground selection lines.

### CROSS-REFERENCE TO RELATED APPLICATIONS

This application claims priority under 35 U.S.C. § 119 to Korean Patent Application Nos. 10-2024-0079753 filed on Jun. 19, 2024, and 10-2024-0107970 filed on Aug. 13, 2024, in the Korean Intellectual Property Office, the disclosures of which are incorporated by reference herein in their entireties.

### BACKGROUND

A semiconductor memory can be classified as a volatile memory, which loses data stored therein when a power is turned off, such as a static random access memory (SRAM) or a dynamic random access memory (DRAM) or a nonvolatile memory, which retains data stored therein even when a power is turned off, such as a flash memory, a phase-change RAM (PRAM), a magnetic RAM (MRAM), a resistive RAM (RRAM), or a ferroelectric RAM (FRAM).

The flash memory device is being widely used as a high-capacity storage medium. In general, the flash memory device stores data or read the stored data by controlling levels of various lines (e.g., a string selection line, a word line, and a ground selection line) connected to a plurality of memory cells. When various lines are controlled individually in units of cell string, the reliability and performance of the flash memory device may be improved, but it is difficult to form lines individually due to the increase in complexity of the process of manufacturing the flash memory device.

### SUMMARY

Implementations of the present disclosure provide a storage device with improved reliability and improved performance and an operation method thereof.

In some implementations, an operation method of a storage device which includes a memory device and a controller controlling the memory device includes performing a normal read operation on a first memory block of the memory device to read first user data, performing an error correction operation on the first user data, and performing a special read operation on the first memory block to read second user data when an error of the first user data is not corrected. The first memory block includes a plurality of cell strings, and the plurality of cell strings share a plurality of ground selection lines. In the normal read operation, the memory device applies a first voltage to at least one ground selection line among the plurality of ground selection lines and applies a second voltage higher than the first voltage to remaining ground selection lines. In the special read operation, the memory device applies the second voltage or a third voltage higher than the second voltage to the plurality of ground selection lines.

In some implementations, a storage device includes a memory device that includes a first memory block, and a controller that performs a normal read operation on the first memory block to read first user data. When an error of the first user data is not corrected, the controller performs a special read operation on the first memory block to read second user data. The first memory block includes a plurality of cell strings sharing a plurality of ground selection lines. In the normal read operation, the memory device applies a first voltage to at least one ground selection line of the plurality of ground selection lines and applies a second voltage higher than the first voltage to remaining ground selection lines. In the special read operation, the memory device applies the second voltage or a third voltage higher than the second voltage to the plurality of ground selection lines.

In some implementations, an operation method of a memory device which includes a first memory block including a plurality of cell strings sharing a plurality of ground selection lines includes reading first user data by performing a normal read operation on the first memory block in response to a first command and a first address received from a controller, transmitting the first user data to the controller, reading second user data by performing a special read operation on the first memory block in response to a second command and the first address received from the controller, and transmitting the second user data to the controller. In the normal read operation, a first voltage is applied to at least one ground selection line among the plurality of ground selection lines and a second voltage higher than the first voltage is applied to remaining ground selection lines. In the special read operation, the second voltage or a third voltage higher than the second voltage is applied to the plurality of ground selection lines.

### BRIEF DESCRIPTION OF THE DRAWINGS

The above and other objects and features of the present disclosure will become apparent by describing in detail implementations thereof with reference to the accompanying drawings.

FIG. 1 is a block diagram illustrating an example storage device.

FIG. 2 is a block diagram illustrating an example controller of FIG. 1.

FIG. 3 is a block diagram illustrating an example memory device of FIG. 1.

FIG. 4 is a circuit diagram illustrating an example first memory block of a memory cell array of FIG. 3.

FIG. 5 is a plan view of the example first memory block of FIG. 4.

FIGS. 6A and 6B are diagrams for describing an example method of controlling a first memory block of FIGS. 4 and 5.

FIG. 7 is a flowchart illustrating an example operation of a storage device.

FIGS. 8A to 8C are diagrams for describing an example normal read operation in operation S110 of FIG. 7.

FIGS. 9A and 9B are diagrams for describing am example special read operation in operation S130 of FIG. 7.

FIG. 10 is a flowchart illustrating an example ground selection transistor (GST)-care operation in operation S150 of FIG. 7.

FIGS. 11A and 11B are diagrams for describing an example GST-repair operation in operation S151-2 of FIG. 10.

FIG. 12 is a flowchart illustrating an example GST-care operation in operation S150 of FIG. 7.

FIG. 13 is a flowchart illustrating an example operation of a storage device of FIG. 1.

FIG. 14 is a flowchart illustrating an example operation of a storage device of FIG. 1.

FIGS. 15A to 15C are diagrams for describing a coded GSL structure of a memory block included in a memory device of FIG. 1.

FIG. 16 is a view for describing an example memory device.

FIG. 17 is a diagram illustrating an example system including an example storage device.

### DETAILED DESCRIPTION

Below, implementations of the present disclosure will be described in detail and clearly to such an extent that an ordinary one in the art easily carries out the present disclosure.

In the detailed description or drawings, function blocks which are expressed by using the terms “unit”, “module”, etc. or are illustrated in drawings may be implemented in the form of hardware, software, or a combination thereof, which is configured to perform a specific function.

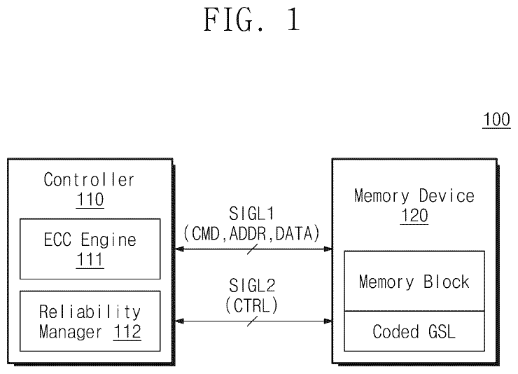

FIG. 1 is a block diagram illustrating a storage device according to an implementation of the present disclosure. Referring to FIG. 1, a storage device 100 may include a controller 110 and a memory device 120. In some implementations, the storage device 100 may be a high-capacity storage device, which is configured to store data in a computing system, such as a solid state drive (SSD) or a universal flash storage (UFS) card, but the present disclosure is not limited thereto. Alternatively, the storage device 100 may be a high-capacity storage medium included in a mobile system such as a mobile phone, a smartphone, a tablet personal computer (PC), a wearable device, a health care device, or an Internet of things (IoT) device. Alternatively, the storage device 100 may be a high-capacity storage medium included in the personal computer, a laptop computer, a server, a media player, an automotive device such as a navigation system, etc.

The controller 110 may be configured to control the memory device 120. For example, the controller 110 may store data in the memory device 120 or may read data stored in the memory device 120. For example, the controller 110 may transmit a command CMD and an address ADDR to the memory device 120 through first signal lines SIGL1 and may exchange data “DATA” with the memory device 120 through the first signal lines SIGL1. In some implementations, the first signal lines SIGL1 may be data signal lines (e.g., DQ lines). The controller 110 may transmit control signals CTRL to the memory device 120 through second signal lines SIGL2. In some implementations, the control signals CTRL may be used to classify signals transmitted/received through the first signal lines SIGL1 into the command CMD, the address ADDR, and the data “DATA”. However, the present disclosure is not limited thereto.

The memory device 120 may operate under control of the controller 110. For example, in response to signals received from the controller 110, the memory device 120 may store data or may output the stored data. In some implementations, the memory device 120 may include a NAND flash memory device, but the present disclosure is not limited thereto. For example, the memory device 120 may include various memories such as a dynamic random access memory (DRAM), a static RAM (SRAM), a phase-change RAM (PRAM), a magnetic RAM (MRAM), a resistive RAM (RRAM), or a ferroelectric RAM (FRAM).

In some implementations, the controller 110 may include an error correction code (ECC) engine 111 and a reliability manager 112. For example, due to the physical characteristic of the memory device 120, an error may occur in data stored in the memory device 120. The ECC engine 111 of the controller 110 may be configured to detect and correct an error of data read from the memory device 120. As an example, when the error included in the data exceeds the error correction capability of the ECC engine 111, the error of the data is incapable of being corrected. The event that the ECC engine 111 is incapable of correcting the error of the data is called an uncorrectable ECC (UECC). In the UECC situation, the reliability manager 112 of the controller 110 may perform various reliability operations such that the error included in the data is reduced within the error correction capability of the ECC engine 111. As an example, the reliability operations may include various operations for the memory device 120, such as a valley search operation, a predetermined table (PDT) read operation, or a soft decision decoding operation.

In some implementations, the memory device 120 may include a plurality of memory blocks. Each of the plurality of memory blocks may include a coded GSL structure. For example, as will be described later, each of the plurality of memory blocks may include a plurality of cell strings sharing a ground selection line. Because the cell strings share the ground selection line, the performance of the memory device 120 may be reduced (e.g., a word line setup time may increase). To solve the above issue, threshold voltages of the ground selection transistors of each of the plurality of cell strings may be differently set, and voltages of ground selection lines may be controlled. According to this method, the plurality of cell strings may be individually or separately controlled (i.e., only a selected cell string may be electrically connected to a common source line). A memory block with the coded GSL structure will be described in detail with reference to the following drawings.

In some implementations, due to the physical characteristic (e.g., retention or hot electron injection) of the ground selection transistor, the threshold voltage of the ground selection transistor may change; in this case, the plurality of cell strings may not be individually or separately controlled through the control of the ground selection lines. This may mean that data (or user data) stored in a memory block are not normally read or an error is not corrected through various other reliability operations.

In some implementations of the present disclosure, in the UECC situation, the memory device 120 may perform the read operation by turning on all ground selection transistors of a memory block under control of the controller 110. In this case, even though the threshold voltages of the ground selection transistors change, because all the ground selection transistors are turned on, data may be normally read from the memory block. The operation of the storage device 100 according to an implementation of the present disclosure will be described in detail with reference to the following drawings.

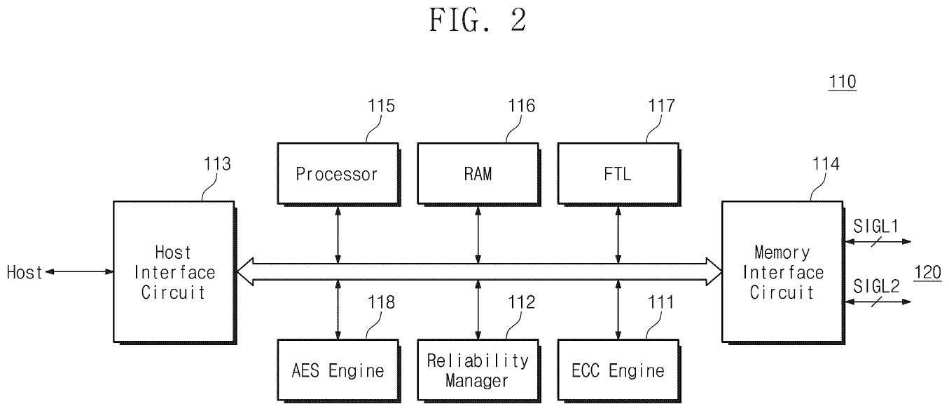

FIG. 2 is a block diagram illustrating a controller of FIG. 1. Referring to FIGS. 1 and 2, the controller 110 may include the ECC engine 111, the reliability manager 112, a host interface circuit 113, a memory interface circuit 114, a processor 115, a random access memory (RAM) 116, a flash translation layer (FTL) 117, and an AES engine 118.

The ECC engine 111 may be configured to correct an error of data stored in the memory device 120. When an error of data is not corrected by the ECC engine 111, the reliability manager 112 may perform various reliability operations.

The host interface circuit 113 may communicate with an external host based a host interface. In some implementations, the host interface may include at least one of various interfaces such as an ATA (Advanced Technology Attachment) interface, an SATA (Serial ATA) interface, an e-SATA (external SATA) interface, an SCSI (Small Computer Small Interface) interface, an SAS (Serial Attached SCSI) interface, a PCI (Peripheral Component Interconnection) interface, a PCIe (PCI express) interface, an NVMe (NVM express) interface, an IEEE 1394 interface, an USB (Universal Serial Bus) interface, an SD (Secure Digital) card interface, an MMC (Multi-Media Card) interface, an eMMC (embedded Multi-Media Card) interface, an UFS (Universal Flash Storage) interface, an eUFS (embedded Universal Flash Storage) interface, and a CF (Compact Flash) card interface.

The memory interface circuit 113 may communicate with the memory device 120 based on a memory interface. In some implementations, the memory interface may include one of interfaces such as a toggle interface and an open NAND flash interface (ONFI), and the first and second signal lines SIGL1 and SIGL2 may be configured to comply with the memory interface.

The processor 115 may control all the operations of the controller 110. For example, the processor 115 may execute various applications on the controller 110. The RAM 116 may be configured to store various information necessary for the controller 110 to operate. In some implementations, the RAM 116 may be used as a working memory, a cache memory, or a buffer memory of the controller 110.

The FTL 117 may perform maintenance operations for efficiently managing or using the memory device 120. In some implementations, the maintenance operations may include an address mapping operation, a wear-leveling operation, a garbage collection operation, etc.

The address mapping operation of the FTL 117 may refer to an operation of translating a logical address received from the external host into a physical address to be used to actually store data in the memory device 120. In some implementations, the FTL 117 may perform the address mapping operation by using L2P map data. The wear-leveling operation of the FTL 117 may refer to an operation of preventing excessive deterioration of a specific memory block among the memory blocks included in the memory device 120. For example, the FTL 117 may allocate the memory blocks included in the memory device 120 so as to be used uniformly, and thus, the excessive deterioration of the specific memory block may be prevented. In some implementations, the wear-leveling operation of the FTL 117 may be implemented through a firmware technology for balancing erase counts of the memory blocks of the memory device 120. The garbage collection operation of the FTL 117 may refer to an operation of securing a memory block or a capacity available in the memory devices 120 by copying valid data of a source memory block to a target memory block and then switching the source memory block into a free block or erasing the source memory block. The FTL 117 may further perform various management operations such as a bad block management operation, in addition to the above operations. In some implementations, some or all of the functions of the FTL 117 may be implemented through software, hardware, or a combination thereof.

The AES engine 118 may perform at least one of an encryption operation and a decryption operation on data input to the controller 110 by using a symmetric-key algorithm.

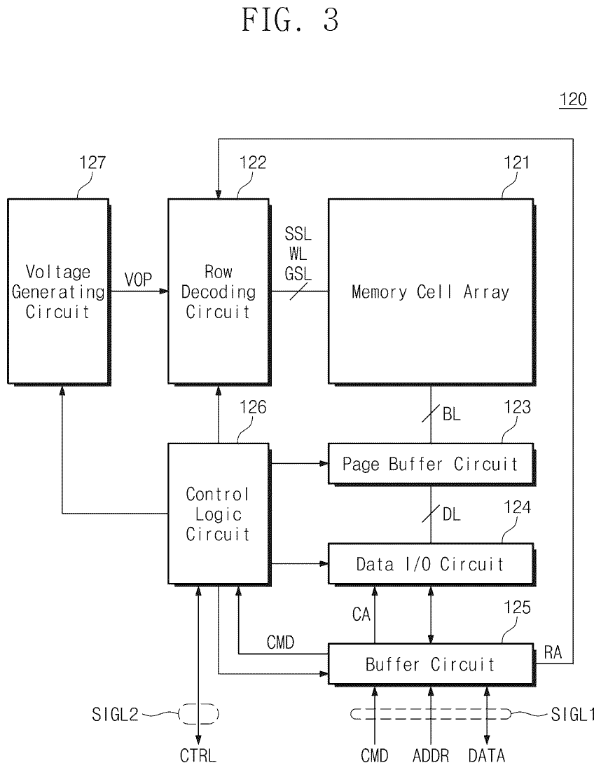

FIG. 3 is a block diagram illustrating a memory device of FIG. 1. Referring to FIGS. 1 and 3, the memory device 120 may include a memory cell array 121, a row address decoding circuit 122, a page buffer circuit 123, a data input/output circuit 124, a buffer circuit 125, a control logic circuit 126, and a voltage generating circuit 127.

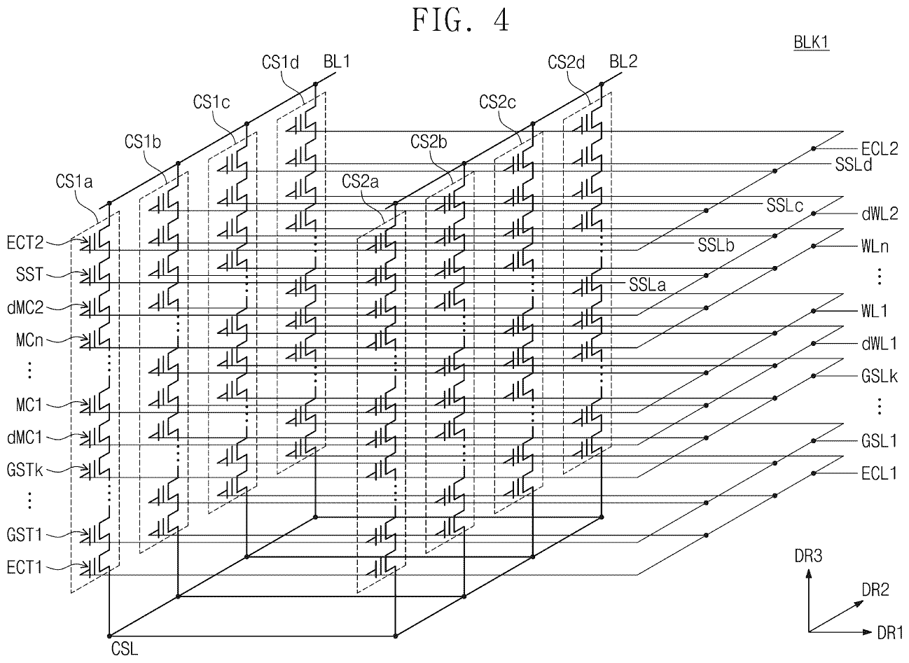

The memory cell array 121 may include a plurality of memory blocks. Each of the plurality of memory blocks may include a plurality of cell strings. Each of the plurality of cell strings may include a plurality of cell transistors stacked in a direction perpendicular to a substrate. The plurality of cell transistors may be connected in series between bit lines BL and a common source line. The plurality of cell transistors may be connected to string selection lines SSL, word lines WL, and ground selection lines GSL. In some implementations, each of the plurality of memory blocks may have the coded GSL structure, which will be described in detail with reference to FIGS. 4 to 6B.

The row decoding circuit 122 may be connected to the memory cell array 111 through the string selection lines SSL, the word lines WL, and the ground selection lines GSL. The row decoding circuit 122 may operate under control of the control logic circuit 126. For example, under control of the control logic circuit 126, the row decoding circuit 122 may decode a row address RA received from the buffer circuit 125; based on a decoding result, the row decoding circuit 123 may control or drive the string selection lines SSL, the word lines WL, and the ground selection lines GSL or may control voltages to be applied to the string selection lines SSL, the word lines WL, and the ground selection lines GSL.

The page buffer circuit 123 may be connected to the memory cell array 111 through the bit lines BL. The page buffer circuit 123 may be connected to the data input/output circuit 124 through data lines DL. The page buffer circuit 123 may operate under control of the control logic circuit 126. For example, in the program operation of the memory device 120, the page buffer circuit 123 may control voltages of the bit lines BL based on data to be programmed in the memory cell array 121 under control of the control logic circuit 126. Alternatively, in the read operation of the memory device 120, the page buffer circuit 123 may sense voltages of the bit lines BL and may store the sensed voltages as read data.

The data input/output circuit 124 may be connected to the page buffer circuit 130 through the data lines DL. The data input/output circuit 124 may receive a column address CA from the buffer circuit 125. The data input/output circuit 124 may transmit the data read by the page buffer circuit 123 to the buffer circuit 125 depending on the column address CA. The data input/output circuit 124 may transmit the data received from the buffer circuit 125 to the page buffer circuit 124, based on the column address CA.

The buffer circuit 125 may receive the command CMD and the address ADDR through the first signal lines SIGL1 from the controller 110 and may exchange the data “DATA” with the controller 110 through the first signal lines SIGL1. In some implementations, the first signal lines SIGL1 may include signal lines for transmitting/receiving a data signal (e.g., DQ) and a data strobe signal (e.g., DQS).

The buffer circuit 125 may operate under control of the control logic circuit 126. For example, the control logic circuit 126 may exchange the control signals CTRL with the controller 110 through the second signal lines SIGL2. The control logic circuit 126 may control the buffer circuit 125 based on the control signals CTRL such that the buffer circuit 127 routes the command CMD, the address ADDR, and the data “DATA”. Under control of the control logic circuit 126, the buffer circuit 125 may classify signals received through the first signal lines SIGL1 as the command CMD or the address ADDR. The buffer circuit 125 may transfer the command CMD to the control logic circuit 126. The buffer circuit 125 may transfer the row address RA of the address ADDR to the row decoding circuit 120 and may transfer the column address CA of the address ADDR to the data input/output circuit 124. The buffer circuit 125 may exchange the data “DATA” with the data input/output circuit 124.

The control logic circuit 126 may decode the command CMD received from the buffer circuit 125 and may control the memory device 120 or various components of the memory device 120 based on a decoding result.

Under control of the control logic circuit 126, the voltage generating circuit 127 may generate various operating voltages VOP which are used in the memory device 120. In some implementations, the operating voltages VOP may include various voltages such as program voltages, pass voltages, selection read voltages, non-selection read voltages, erase voltages, verify voltages, an on-voltage, and an off-voltage. Below, various voltages which are used to describe implementation of the present disclosure may be include in the operating voltages VOP generated by the voltage generating circuit 127.

FIG. 4 is a circuit diagram illustrating a first memory block included in a memory cell array of FIG. 3. A structure of a first memory block BLK1 will be described with reference to FIG. 4, but the present disclosure is not limited thereto. For example, the memory cell array 121 may include a plurality of memory blocks, each of which is similar in structure to the first memory block BLK1 of FIG. 4.

In some implementations, the first memory block BLK1 to be described with reference to FIG. 4 may correspond to a physical erase unit of the memory device 120. However, the present disclosure is not limited thereto. For example, the memory device 120 may perform the erase operation in units of page, word line, sub-block, or plane.

In some implementations, the first memory block BLK1 to be described with reference to FIG. 4 is provided only as an example. The number of cell strings may increase or decrease, and the number of rows of cell strings and the number of columns of cell strings may increase or decrease depending on the number of cell strings. Also, the numbers of cell transistors GST, GST, MC, DMC, and SST of the first memory block BLK1 may increase or decrease, and the height of the first memory block BLK1 may increase or decrease depending on the numbers of cell transistors. In addition, the number of lines GSL, WL, DWL, and SSL connected to the cell transistors may increase or decrease depending on the number of cell transistors.

Referring to FIGS. 3 and 4, the first memory block BLK1 may include a plurality of cell strings CS1a, CS1b, CS1c, CS1d, CS2a, CS2b, CS2c, and CS2d. The plurality of cell strings CS1a to CS2d may be disposed along a first direction DR1 and a second direction DR2 to form rows and columns.

The plurality cell strings CS1a to CS2d may be connected to bit lines BL1 and BL2. For example, each of the bit lines BL1 and BL2 may extend along the second direction DR2. The cell strings CS1a, CS1b, CS1c, and CS1d located at the same column, that is, the first column from among the plurality of cell strings CS1a to CS2d may be connected to the first bit line BL1, and the cell strings CS2a, CS2b, CS2c, and CS2d located at the same column, that is, the second column from among the plurality of cell strings CS1a to CS2d may be connected to the second bit line BL2.

The 1a-th cell string CS1a may include a plurality of cell transistors connected in series between the first bit line BL1 and a common source line CSL. The plurality of cell transistors of the 1a-th cell string CS1a located at the first column and first row may include a first erase control transistor ECT1, a plurality of ground selection transistors GST1 to GSTk, dummy memory cells dMC1 and dMC2, a plurality of memory cells MC1 to MCn, a string selection transistor SST, and a second erase control transistor ECT2. In some implementations, each of the plurality of cell transistors may be implemented with a charge trap flash (CTF) memory cell.

The plurality of cell transistors of the 1a-th cell string CS1a may be connected in series between the first bit line BL1 and the common source line CSL and may be stacked in a third direction DR3 (or a height direction) which is a direction perpendicular to a plane defined by the first direction DR1 and the second direction DR2 or a substrate. For example, the plurality of memory cells MC1 to MCn may be connected in series and may be stacked in the third direction DR3 being a direction perpendicular to the substrate. The string selection transistor SST may be provided between the plurality of memory cells MC1 to MCn and the first bit line BL1. The plural of ground selection transistors GST1 to GSTk may be connected in series and may be stacked in the third direction DR3 (or a height direction) being a direction perpendicular to the substrate. The plurality of ground selection transistors GST1 to GSTk connected in series may be provided between the plurality of serially-connected memory cells MC1 to MCn and the common source line CSL.

In some implementations, the first dummy memory cell dMC1 may be provided between the plurality of memory cells MC1 to MCn and the plurality of ground selection transistors GST1 to GSTk. In some implementations, the second dummy memory cell dMC2 may be provided between the plurality of memory cells MC1 to MCn and the string selection transistor SST.

In some implementations, the first erase control transistor ECT1 may be provided between the plurality of ground selection transistors GST1 to GSTk and the common source line CSL. The second erase control transistor ECT2 may be provided between the string selection transistor SST and the first bit line BL1. The first and second erase control transistors ECT1 and ECT2 may be used to charge the channel of the 1a-th cell string CS1a with an erase voltage or to erase the first memory block BLK1, based on a gate induced drain leakage (GIDL) phenomenon.

For convenience of description, the structure of the 1a-th cell string CS1a is described, but the present disclosure is not limited thereto. For example, each of the remaining cell strings CS1b to CS1d and CS2a to CS2d may be similar in structure to the 1a-th cell string CS1a.

The first erase control transistors ECT1 of the plurality of cell strings CS1a to CS2d may be connected in common to a first erase control line ECL1. The second erase control transistors ECT2 of the plurality of cell strings CS1a to CS2d may be connected in common to a second erase control line ECL2.

Memory cells located at the same height from the substrate from among the plurality of memory cells MC1 to MCn may be connected in common to the same word line, and memory cells located at another height from among the plurality of memory cells MC1 to MCn may be connected in common to another word line. For example, the first memory cells MC1 of the plurality of cell strings CS1a to CS2d may be located at the same height from the substrate and may be connected in common to a first word line WL1. The n-th memory cells MCn of the plurality of cell strings CS1a to CS2d may be located at the same height from the substrate and may be connected in common to an n-th word line WLn.

In some implementations, the first dummy memory cells dMC1 of the plurality of cell strings CS1a to CS2d may be located at the same height from the substrate and may be connected in common to a first dummy word line dWL1. The second dummy memory cells dMC2 of the plurality of cell strings CS1a to CS2d may be located at the same height from the substrate and may be connected in common to a second dummy word line dWL2.

The string selection transistors SST of the plurality of cell strings CS1a to CS2d may be connected to a plurality of string selection lines SSLa to SSLd. For example, string selection transistors located at the same row may be connected to the same string selection line, and string selection transistors located at different rows may be connected to different string selection lines. In detail, the string selection transistors SST of the cell strings CS1a and CS2a located at the first row may be connected to an a-th string selection line SSLa; the string selection transistors SST of the cell strings CS1b and CS2b located at the second row may be connected to a b-th string selection line SSLb; the string selection transistors SST of the cell strings CS1c and CS2c located at the third row may be connected to a c-th string selection line SSLc; and, the string selection transistors SST of the cell strings CS1d and CS2d located at the fourth row may be connected to a d-th string selection line SSLd.

For brevity of drawing and for convenience of description, the description will be given as each of the plurality of cell strings CS1a to CS2d includes one string selection transistor SST, but the present disclosure is not limited thereto. Each of the plurality of cell strings CS1a to CS2d may include a plurality of string selection transistors, and string selection transistors located at the same row from among string selection transistors located at the same height from the substrate may be connected to the same string selection line; in this case, string selection transistors located at different rows may be connected to different string selection lines.

Ground selection transistors located at the same height from the substrate may be connected to the same ground selection line in common. For example, first ground selection transistors GST1 of the plurality of cell strings CS1a to CS2d may be located at the same height from the substrate and may be connected in common to a first ground selection line GSL1; k-th ground selection transistors GSTk of the plurality of cell strings CS1a to CS2d may be located at the same height from the substrate and may be connected in common to a k-th ground selection line GSLk.

As illustrated in FIG. 4, the plurality of cell strings CS1a to CS2d may be connected in common to the ground selection lines GSL1 to GSLk or may share the ground selection lines GSL1 to GSLk. In this case, as the plurality of cell strings CS1a to CS2d are controlled by the same ground selection line, a ground selection transistor of an unselected cell string may be turned on during the read operation, the verify operation, or the channel recovery operation, thereby causing issues such as the reduction of reliability, the reduction of performance, and an increase in power consumption.

To solve the above issues, the ground selection transistors GST1 to GSKk of the plurality of cell strings CS1a to CS2d may be connected to a ground selection line in units of row such that the plurality of cell strings CS1a to CS2d are controlled individually or in units of row. In this case, a ground selection transistor of an unselected cell string may be turned off during the read operation, the verify operation, or the channel recovery operation, and thus, issues such as the reduction of reliability, the reduction of performance, and an increase in power consumption may be solved.

However, the physical limitation of the first memory block BLK1 may make it difficult (or impossible) to implement a structure in which the ground selection transistors GST1 to GSKk of the plurality of cell strings CS1a to CS2d are connected to a ground selection line in units of row. In this case, the plurality of cell strings CS1a to CS2d may be individually controlled by individually setting a threshold voltage of each of the ground selection transistors GST1 to GSKk of the plurality of cell strings CS1a to CS2d and controlling voltages of the plurality of ground selection lines GSL1 to GSLk. In the present disclosure, the above structure is called the coded GSL structure.

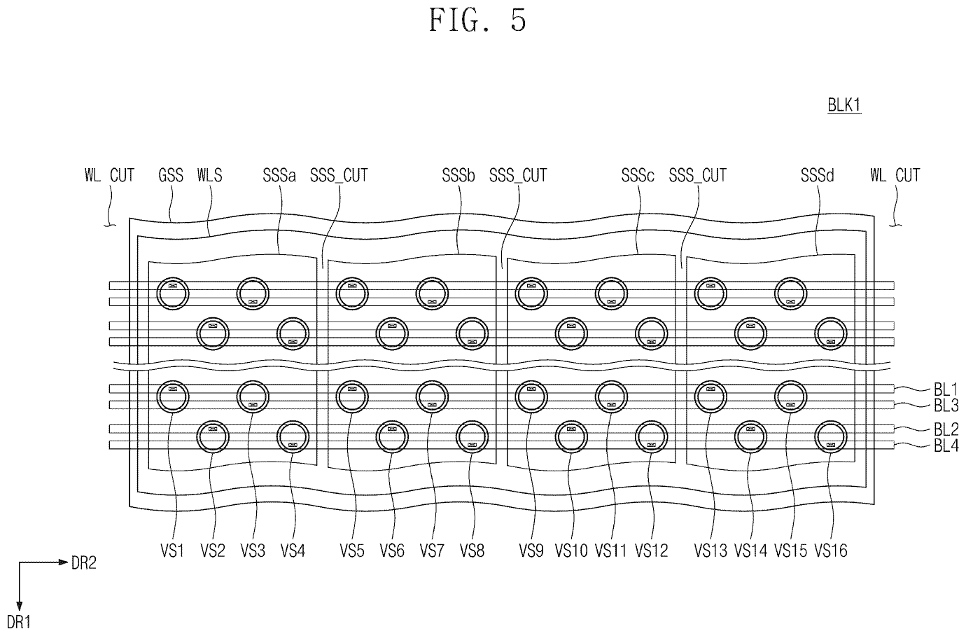

FIG. 5 is a plan view of a first memory block of FIG. 4. For convenience of description, some components of the first memory block BLK1 are omitted. However, the present disclosure is not limited thereto. Referring to FIGS. 4 and 5, the first memory block BLK1 may be formed on the substrate. The first memory block BLK1 may include a ground selection structure GSS, a word line structure WLS, and a plurality of string selection structures SSSa, SSSb, SSSc, and SSSd. The ground selection structure GSS, the word line structure WLS, and the plurality of string selection structures SSSa, SSSb, SSSc, and SSSd may be provided between word line cuts WL_CUT and may be stacked along a direction (e.g., the third direction DR3) perpendicular to the substrate defined by the first direction DR1 and the second direction DR2.

The plurality of string selection structures SSSa, SSSb, SSSc, and SSSd may extend along the first direction DR1 and may be electrically separated from each other by string selection cuts SS_CUT. The first memory block BLK1 may include a plurality of vertical structures VS1 to VS16. The plurality of vertical structures VS1 to VS16 may penetrate the ground selection structure GSS, the word line structure WLS, and the plurality of string selection structures SSSa, SSSb, SSSc, and SSSd. For example, the first to fourth vertical structures VS1 to VS4 may penetrate the ground selection structure GSS, the word line structure WLS, and the a-th string selection structure SSSa; the fifth to eighth vertical structures VS5 to VS8 may penetrate the ground selection structure GSS, the word line structure WLS, and the b-th string selection structure SSSb; the ninth to twelfth vertical structures VS9 to VS12 may penetrate the ground selection structure GSS, the word line structure WLS, and the c-th string selection structure SSSca; and, the thirteenth to sixteenth vertical structures VS13 to VS16 may penetrate the ground selection structure GSS, the word line structure WLS, and the d-th string selection structure SSSd.

The plurality of vertical structures VS1 to VS16 may be connected to a plurality of bit lines BL1, BL2, BL3, and BL4 extending along the second direction DR2. For example, the first, fifth, ninth, and thirteenth vertical structures VS1, VS5, VS9, and VS13 may be connected to the first bit line BL1; the second, sixth, tenth, and fourteenth vertical structures VS2, VS6, VS10, and VS14 may be connected to the second bit line BL2, the third, seventh, eleventh, and fifteenth vertical structures VS3, VS7, VS11, and VS15 may be connected to the third bit line BL3, and the fourth, eighth, twelfth, and sixteenth vertical structures VS4, VS8, VS12, and VS16 may be connected to the fourth bit line BL4.

In some implementations, each of the plurality of vertical structures VS1 to VS16 may form a cell string. For example, the first and second vertical structures VS1 and VS2 of FIG. 5 may respectively correspond to the 1a-th and 2a-th cell strings CS1a and CS2a of FIG. 2; the fifth and sixth vertical structures VS5 and VS6 of FIG. 5 may respectively correspond to the 1b-th and 2b-th cell strings CS1b and CS2b of FIG. 4; the ninth and tenth vertical structures VS9 and VS10 of FIG. 5 may respectively correspond to the 1c-th and 2c-th cell strings CS1c and CS2c of FIG. 4; and, the thirteenth and fourteenth vertical structures VS13 and VS14 of FIG. 5 may respectively correspond to the 1d-th and 2d-th cell strings CS1d and CS2d of FIG. 4.

In the structure of the first memory block BLK1 described with reference to FIG. 5, four string selection structures SSSa to SSSd may respectively correspond to the four string selection lines SSLa to SSLd of FIG. 4. That is, in the first memory block BLK1 described with reference to FIG. 5, cell strings connected to the four string selection lines SSLa to SSLd may share ground selection lines. Below, for convenience of description, an SSL-GSL structure of the first memory block BLK1 described with reference to FIGS. 4 and 5 may be a “4SSL-1GSL structure”. This may indicate a structure where cell strings connected to four string selection lines share one ground selection line.

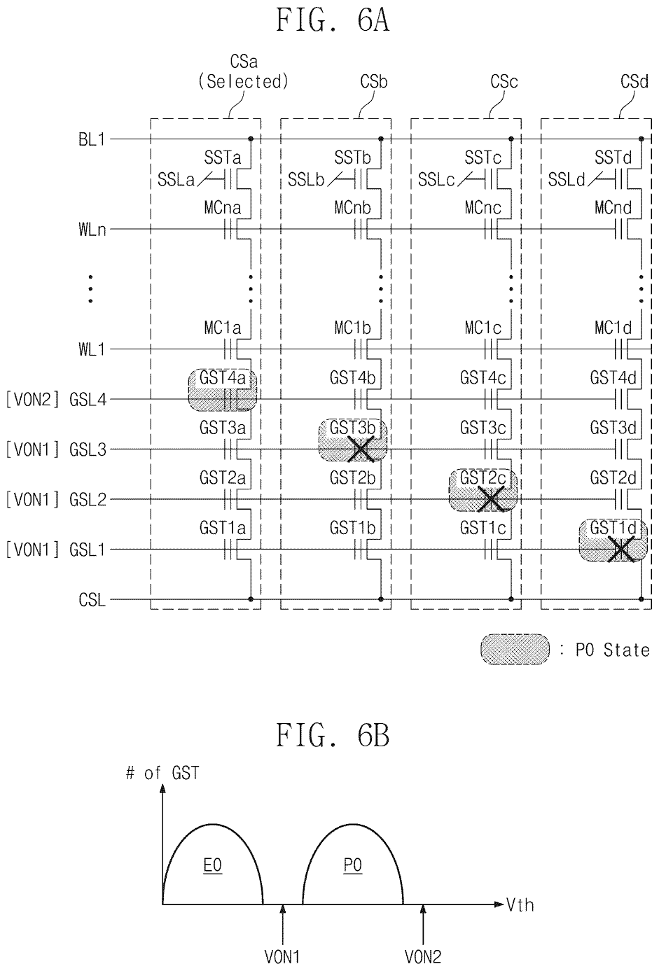

FIGS. 6A and 6B are diagrams for describing a method of controlling a first memory block of FIGS. 4 and 5. Below, for convenience of description, implementations of the present disclosure will be described based on the plurality of cell strings CSa, CSb, CSc, and CSd connected to the first bit line BL1. Also, some (e.g., dummy memory cells and erase control transistors) of cell transistors included in each of the plurality of cell strings CSa, CSb, CSc, and CSd are omitted. However, the present disclosure is not limited thereto.

Below, for brevity of drawing and for convenience of description, some ground selection lines GSL and some ground selection transistors GST are illustrated in a drawing, but the present disclosure is not limited thereto. For example, in the following drawings, ground selection transistors are illustrated as being directly connected to the common source line CSL, but additional ground selection transistors may further exist between the illustrated ground selection transistors or the dummy ground selection transistors and the common source line CSL.

Referring to FIGS. 4, 5, 6A, and 6B, the first memory block BLK1 may include the a-th to d-th cell strings CSa to CSd. Each of the a-th to d-th cell strings CSa to CSd may be connected between the first bit line BL1 and the common source line CSL. The a-th cell string CSa may include a plurality of ground selection transistors GST1a to GST4a, a plurality of memory cells MC1a to MCna, and an a-th string selection transistor SSTa. The b-th cell string CSb may include a plurality of ground selection transistors GST1b to GST4b, a plurality of memory cells MC1b to MCnb, and a b-th string selection transistor SSTb. The c-th cell string CSc may include a plurality of ground selection transistors GST1c to GST4c, a plurality of memory cells MC1c to MCnc, and a c-th string selection transistor SSTc. The d-th cell string CSd may include a plurality of ground selection transistors GST1d to GST4d, a plurality of memory cells MC1d to MCnd, and a d-th string selection transistor SSTd.

The string selection transistors SSTa of the a-th cell string CSa may be connected to the a-th string selection line SSLa; the string selection transistors SSTb of the b-th cell string CSb may be connected to the b-th string selection line SSLb; the string selection transistors SSTc of the c-th cell string CSc may be connected to the c-th string selection line SSLc; and, the string selection transistors SSTd of the d-th cell string CSd may be connected to the d-th string selection line SSLd.

The ground selection transistors GST1a to GST4a, GST1b to GST4b, GST1c to GST4c, and GST1d to GST4d and the memory cells MC1a to MCna, MC1b to MCnb, MC1c to MCnc, and MC1d to MCnd of the a-th to d-th cell strings CSa to CSd may be connected to the plurality of ground selection lines GSL1 to GSL4 and the plurality of word lines WL1 to WLn. For example, the first memory cells MC1a, MC1b, MC1c, and MC1d of the a-th to d-th cell strings CSa to CSd may be connected to the first word line WL1, and the n-th memory cells MCna, MCnb, MCnc, and MCnd of the a-th to d-th cell strings CSa to CSd may be connected to the n-th word line WLn.

The ground selection transistors GST1a, GST1b, GST1c, and GST1d of the a-th to d-th cell strings CSa to CSd may be connected to the first ground selection line line GSL1; the ground selection transistors GST2a, GST2b, GST2c, and GST2d of the a-th to d-th cell strings CSa to CSd may be connected to the second ground selection line line GSL2; the ground selection transistors GST3a, GST3b, GST3c, and GST3d of the a-th to d-th cell strings CSa to CSd may be connected to the third ground selection line line GSL3; and, the ground selection transistors GST4a, GST4b, GST4c, and GST4d of the a-th to d-th cell strings CSa to CSd may be connected to the fourth ground selection line line GSL4.

In some implementations, while the memory device 100 operates, one of the plurality of cell strings CSa to CSd may be selected, and the remaining cell strings may not be selected. In this case, a threshold voltage of each of the plurality of ground selection transistors GST1a to GST4d may be set such that the remaining unselected cell strings among the plurality of cell strings CSa to CSd other than the selected cell string are not electrically connected to the common source line CSL.

For example, as illustrated in FIG. 6B, a threshold voltage or a threshold voltage distribution of a 0-th program state P0 may be higher than a threshold voltage or a threshold voltage distribution of a 0-th erase state E0. In this case, a ground selection transistor having the 0-th program state P0 may be turned off by a first on-voltage VON1 and may be turned on by a second on-voltage VON2. A ground selection transistor of the 0-th erase state E0 may be turned on by the first on-voltage VON1 and may be turned on by the second on-voltage VON2.

The threshold voltages of 4a-th, 3b-th, 2c-th, and 1d-th ground selection transistors GST4a, GST3b, GST2c, and GST1d among the plurality of ground selection transistors GST1a to GST4a may be set to the 0-th program state P0. In this case, as the first on-voltage VON1 or the second on-voltage VON2 is applied to each of the plurality of ground selection lines GSL1 to GSL4, the remaining unselected cell strings among the plurality of cell strings CSa to CSd other than the selected cell string may not be electrically connected to the common source line CSL.

In detail, it is assumed that the a-th cell string CSa is a selected cell string. In this case, the first on-voltage VON1 may be applied to the first to third ground selection line lines GSL1 to GSL3, and the second on-voltage VON2 may be applied to the fourth ground selection lines GSL4. As the first on-voltage VON1 is applied to the first ground selection line GSL1, the 1a-th, 1b-th, and 1c-th ground selection transistors GST1a, GST1b, and GST1c may be turned on, and the ground selection transistor GST1d may be turned off. As the first on-voltage VON1 is applied to the second ground selection line GSL2, the 2a-th, 2b-th, and 2d-th ground selection transistors GST2a, GST2b, and GST2d may be turned on, and the ground selection transistor GST2c may be turned off. As the first on-voltage VON1 is applied to the third ground selection line GSL3, the 3a-th, 3c-th, and 3d-th ground selection transistors GST3a, GST3c, and GST3d may be turned on, and the 3b-th ground selection transistor GST3b may be turned off. As the second on-voltage VON2 is applied to the fourth ground selection line GSL4, the ground selection transistors GST4a, GST4b, GST4c, and GST4d connected to the fourth ground selection line GSL4 may be turned on.

That is, according to the above bias condition associated with the ground selection lines GSL1 to GSL4, because all the ground selection transistors GST1a to GST4a of the a-th cell string CSa being the selected cell string are turned on, the a-th cell string CSa may be electrically connected to the common source line CSL. In contrast, because the 3b-th, 2c-th, and 1d-th ground selection transistors GST3b, GST2c, and GST1d are turned off, the b-th, c-th, and d-th cell strings CSb, CSc, and CSd being the unselected cell strings may be electrically separated from the common source line CSL. Accordingly, issues, which may occur during the operation of the memory device 100, such as the reduction of reliability, the reduction of performance, and the increase in power consumption may be prevented.

In some implementations, the threshold voltage distribution of the 0-th erase state E0 may be different from the threshold voltage distribution of the 0-th program state P0. In some implementations, the threshold voltage distribution of the 0-th erase state E0 may be lower than the threshold voltage distribution of the 0-th program state P0. For example, threshold voltages of ground selection transistors corresponding to the 0-th erase state E0 may be lower than threshold voltages of ground selection transistors corresponding to the 0-th program state P0. In some implementations, the threshold voltages of the ground selection transistors corresponding to the 0-th erase state E0 may be identical to different from threshold voltages of memory cells MC corresponding to an erase state “E”.

In some implementations, the program operation for the ground selection lines GSL1 to GSL4 may be performed to set the ground selection transistors GST4a, GST3b, GST2c, and GST1d to the threshold voltage of the 0-th program state P0. For example, the threshold voltage of the 4a-th ground selection transistor GST4a may be set to the 0-th program state P0 by applying the program voltage to the fourth ground selection line GSL4 and applying the pass voltage to the remaining lines (e.g., GSL1 to GSL3 and WL1 to WLn). The threshold voltage of the 3b-th ground selection transistor GST3b may be set to the 0-th program state P0 by applying the program voltage to the third ground selection line GSL3 and applying the pass voltage to the remaining lines (e.g., GSL1, GSL2, GSL4, and WL1 to WLn). The threshold voltage of the 2c-th ground selection transistor GST2c may be set to the 0-th program state P0 by applying the program voltage to the second ground selection line GSL2 and applying the pass voltage to the remaining lines (e.g., GSL1, GSL3, GSL4, and WL1 to WLn). The threshold voltage of the 1d-th ground selection transistor GST1d may be set to the 0-th program state P0 by applying the program voltage to the first ground selection line GSL1 and applying the pass voltage to the remaining lines (e.g., GSL2, GSL3, GSL4, and WL1 to WLn).

In some implementations, the threshold voltages of the ground selection transistors GST1a to GST4d may be changed due to various factors. For example, as the memory device 100 operates, the threshold voltages of the ground selection transistors GST1a to GST4d may decrease depending on a retention characteristic of the ground selection transistors GST1a to GST4d. Alternatively, as the memory device 100 operates, the read disturbance may occur in the ground selection transistors GST1a to GST4d, thereby causing the increase in the threshold voltages of the ground selection transistors GST1a to GST4d. Alternatively, as the memory device 100 operates, a hot electron injection phenomenon may occur in the ground selection transistors GST1a to GST4d, thereby causing the increase in the threshold voltages of the ground selection transistors GST1a to GST4d. As described above, as the threshold voltages of the ground selection transistors GST1a to GST4d are changed, the memory device 100 may not operate normally; in this case, data stored in memory cells may not be normally read.

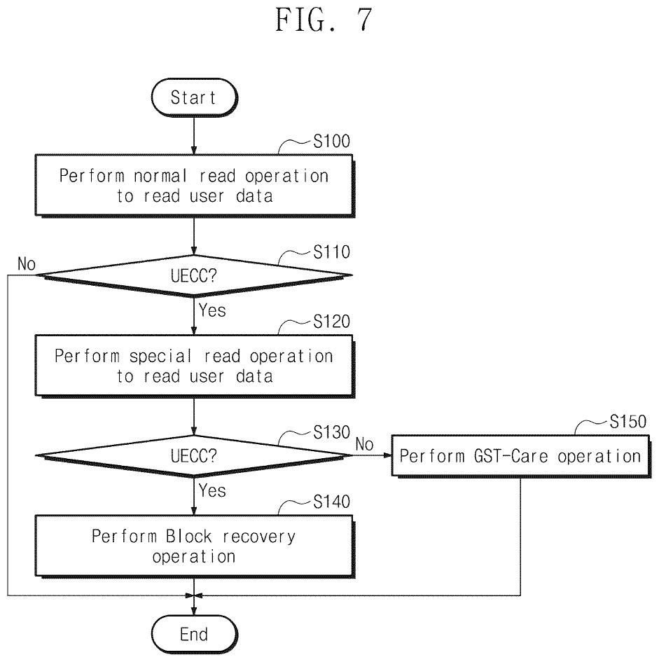

FIG. 7 is a flowchart illustrating an operation of a storage device according to an implementation of the present disclosure. For convenience, the description will be given as an operation according to the flowchart of FIG. 7 is performed by the controller 110 included in the storage device 100. For example, that the controller 110 performs the normal read operation on the memory device 120 may mean that the memory device 120 performs an operation of reading user data from a selected word line of memory cells connected to the selected word line under control of the controller 110. That is, the controller 110 may perform various operations on the memory device 120, which may be understood as the memory device 120 performs various operations under control of the controller 110.

Referring to FIGS. 1 and 7, in operation S100, the controller 110 may perform the normal read operation on the memory device 120 to receive the user data from the memory device 120. In some implementations, the user data refer to data stored in memory cells (e.g., MC1 to MCn) of the memory device 120 and does not mean any functional features or attributes (e.g., are not distinguished from meta data). That is, the term “user data” used in in the specification can mean actual data stored in memory cells.

For example, the controller 110 may transmit a normal read command and address to the memory device 120. The memory device 120 may perform the normal read operation on memory cells corresponding to the address in response to the normal read command. In this case, the memory device 120 may control levels of ground selection lines (e.g., GSL1 to GLS4 of FIG. 6A) such that a cell string corresponding to the address is selected. As an example, as illustrated in FIG. 6A, it is assumed that the a-th cell string CSa is a selected cell string. In this case, during the normal read operation the memory device 120 may apply the first on-voltage VON1 to the first to third ground selection line lines GSL1 to GSL3 and may apply the second on-voltage VON2 to the fourth ground selection lines GSL4. Accordingly, the a-th cell string CSa is electrically connected to the common source line CSL, and the remaining cell strings CSb, CSc, and CSd are not electrically connected to the common source line CSL. The memory device 120 may perform the normal read operation to read the user data. The memory device 120 may transmit the user data to the controller 110.

In operation S110, the controller 110 may determine whether the UECC occurs. For example, the controller 110 may receive the user data from the memory device 120 and may perform the error correction operation on the user data. When the error is corrected, it is determined that the UECC does not occur.

When the error of the user data exceeds the error correction capability of the ECC engine 111, the UECC may occur. In this case (i.e., when the UECC occurs), in operation S120, the controller 110 may read the user data by performing the read operation in which all the ground selection transistors are turned on. For example, as described above, an error of the user data read by the normal read operation of the memory device 120 may not be corrected. In this case, the controller 110 may transmit a command (e.g., a special command) and an address to the memory device 120 such that the read operation is performed in which all the ground selection transistors of the selected memory block are turned on. In response to the received command, the memory device 120 may apply the second on-voltage VON2 to all the ground selection lines regardless of the selected cell string. Accordingly, all the ground selection transistors GST may be turned on. In this case, the user data abnormally read by the change in the threshold voltage of the ground selection transistor may be normally read. Below, for convenience of description, the read operation in which all the ground selection transistors are turned on is referred to as a “special read operation”. The memory device 120 may perform the special read operation to read the user data. The memory device 120 may transmit the user data to the controller 110.

In some implementations, a special command for the special read operation may be defined by the interface protocol between the controller 110 and the memory device 120. Alternatively, the special command may be implemented through a reserved command, a vendor command, or a combination of various other commands. Alternatively, the controller 110 may set information about the special read operation to some bits of the address.

In operation S130, the controller 110 may determine an error correction operation on the user data read in operation S130. When the error correction operation on the user data read in operation S120 is failed (i.e., when the UECC occurs), in operation S140, the controller 110 may perform a block recovery operation. For example, that it is determined in operation S130 that the UECC occurs may mean that the error of the user data is incapable of being corrected. In this case, the controller 110 may perform a copyback operation on the memory block where the user data are stored. Alternatively, the controller 110 may process, as a bad block, the memory block where the user data are stored.

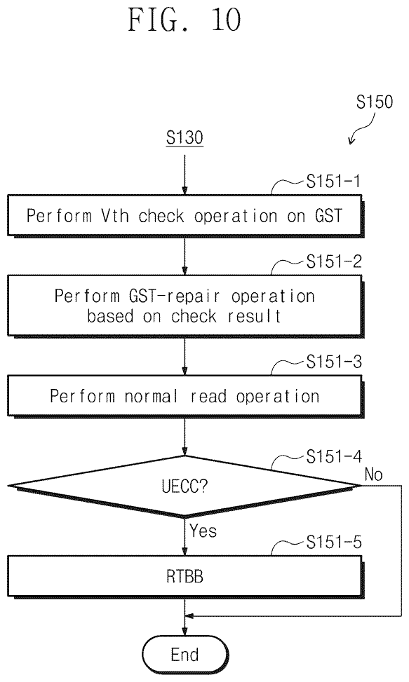

When the error correction operation on the user data read in operation S120 is successful (i.e., when the error is corrected), in operation S150, the controller 110 may perform a GST-care operation. For example, the case where the error of the user data read through the normal read operation is not corrected and the error of the user data read through the special read operation is corrected may mean that threshold voltages of ground selection transistors change. Accordingly, the controller 110 may perform the GST-care operation such that threshold voltages of ground selection transistors have an intended state (e.g., E0, P0, or any other threshold voltage state). The GST-care operation will be described in detail with reference to FIGS. 10 to 12.

In some implementations, when the error of the user data is corrected, the controller 110 may transmit the error-corrected user data to the external host or may use the error-corrected user data for an internal operation (e.g., a garbage collection operation or a copyback operation).

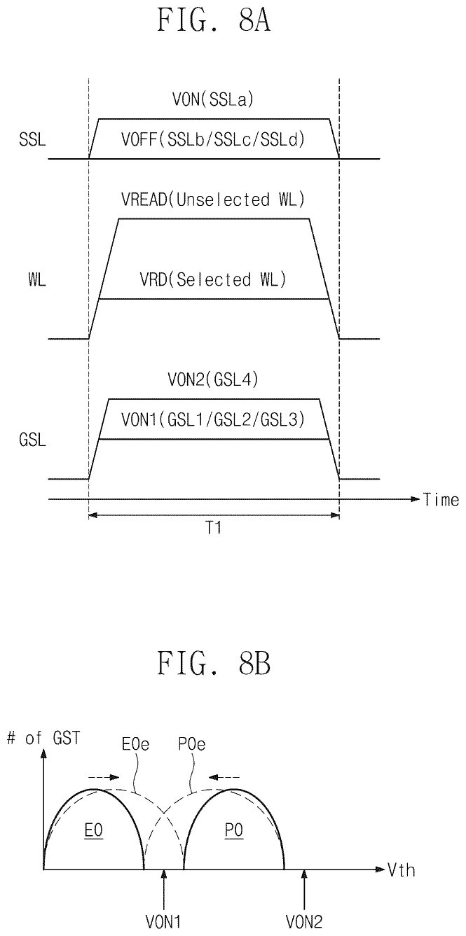

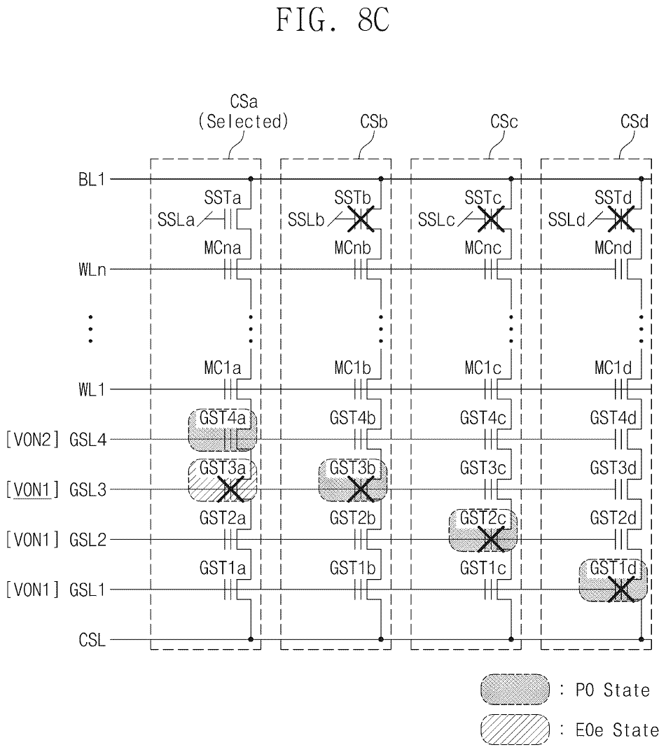

FIGS. 8A to 8C are diagrams for describing the normal read operation in operation S110 of FIG. 7. For convenience of description, components which are unnecessary to describe the normal read operation are omitted. Also, for convenience of description, it is assumed that the memory device 120 uses one read voltage VRD during the normal read operation. However, the present disclosure is not limited thereto. For example, a plurality of read voltages are able to be used depending on the number of data bits (i.e., an SLC, an MLC, a TLC, a QLC, or a PLC) stored in a memory cell and a target page.

Referring to FIGS. 1, 6A, 7, 8A, 8B, and 8C, the memory device 120 may perform the normal read operation under control of the controller 110. For example, it is assumed that the plurality of cell strings CSa, CSb, CSc, and CSd have the coded GSL structure illustrated in FIG. 6A and the a-th cell string CSa is a selected cell string for the normal read operation.

The memory device 120 may perform the normal read operation during a first time period T1. During the normal read operation, the memory device 120 may apply an on-voltage VON to the a-th string selection line SSLa corresponding to the a-th cell string CSa being the selected cell string and may apply an off-voltage VOFF to the b-th, c-th, and d-th cell strings CSb, CSc, and CSd being unselected cell strings. In some implementations, the on-voltage VON may be a high voltage sufficient to turn on the string selection transistor SSTa, and the off-voltage VOFF may be a low voltage sufficient to turn off the string selection transistors SSTb, SSTc, and SSTd.

During the normal read operation, the memory device 120 may apply the read voltage VRD to a selected word line and may apply a non-selection read voltage VREAD to unselected word lines. The read voltage VRD may be a voltage for distinguishing program states of memory cells, and the non-selection read voltage VREAD may be a high voltage sufficient to turn on memory cells regardless of the program states of the memory cells.

During the normal read operation, to connect the a-th cell string CSa to the common source line CSL, the memory device 120 may apply the second on-voltage VON2 to the fourth ground selection line GSL4 and may apply the first on-voltage VON1 to the first, second, and third ground selection lines GSL1, GSL2, and GSL3. In this case, the 1d-th ground selection transistor GST1d of the d-th cell string CSd may be turned off by the first on-voltage VON1 of the first ground selection line GSL1; the 2c-th ground selection transistor GST2c of the c-th cell string CSc may be turned off by the first on-voltage VON1 of the second ground selection line GSL2; the 3b-th ground selection transistor GST3b of the b-th cell string CSb may be turned off by the first on-voltage VON1 of the third ground selection line GSL3. Accordingly, the b-th, c-th, and d-th cell strings CSb, CSc, and CSd being unselected cell strings are not electrically connected to the common source line CSL.

In some implementations, a threshold voltage of a ground selection transistor may change due to the physical characteristic of the ground selection transistor. For example, as illustrated in FIG. 8B, due to the retention characteristic or the hot electron injection, a threshold voltage of a ground selection transistor of the 0-th erase state E0 may increase like a 0-th error erase state E0e, or a threshold voltage of a ground selection transistor of the 0-th program state P0 may decrease like a 0-th error program state P0e. In this case, the ground selection transistor may not normally operate. This may mean that the user data are not normally read from memory cells.

For example, as illustrated in FIG. 8C, it is assumed that the threshold voltage of the 3a-th ground selection transistor GST3a of the a-th cell string CSa increases. That is, the 3a-th ground selection transistor GST3a may have the 0-th error erase state E0e. In this case, the 3a-th ground selection transistor GST3a may be turned off by the first on-voltage VON1 applied to the third ground selection line GSL3. That is, the a-th cell string CSa being a selected cell string is not electrically connected to the common source line CSL. This means that a voltage of the bit line BL does not vary depending on a threshold voltage of a memory cell connected to the selected word line. That is, the user data are not normally read.

As described above, when a threshold voltage of a ground selection transistor changes, a selected cell string may not be electrically connected to the common source line CSL, that is, the user data may not be normally read. Alternatively, although not illustrated in drawings, when a threshold voltage of a ground selection transistor changes, an unselected cell string may be electrically connected to the common source line CSL. In this case, because the channel loading increases, a word line may not be set up to a target level during a given time (i.e., a time for the normal read operation). This may also mean that the user data are not normally read. In other words, the user data may include a plurality of errors. In this case, the error of the user data may not be corrected through the error correction operation of the controller 110 (i.e., UECC occurrence).

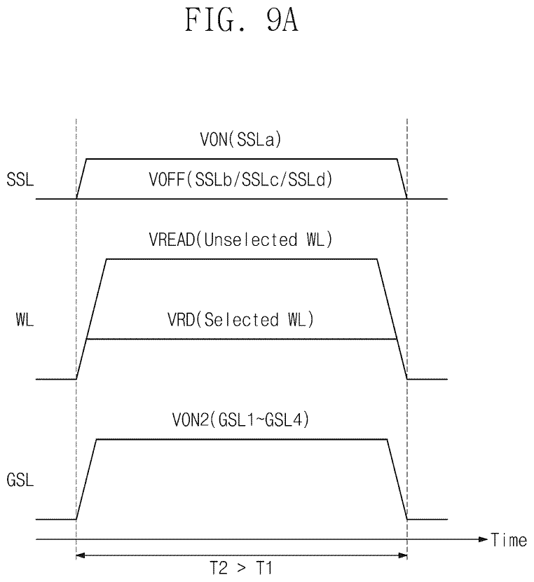

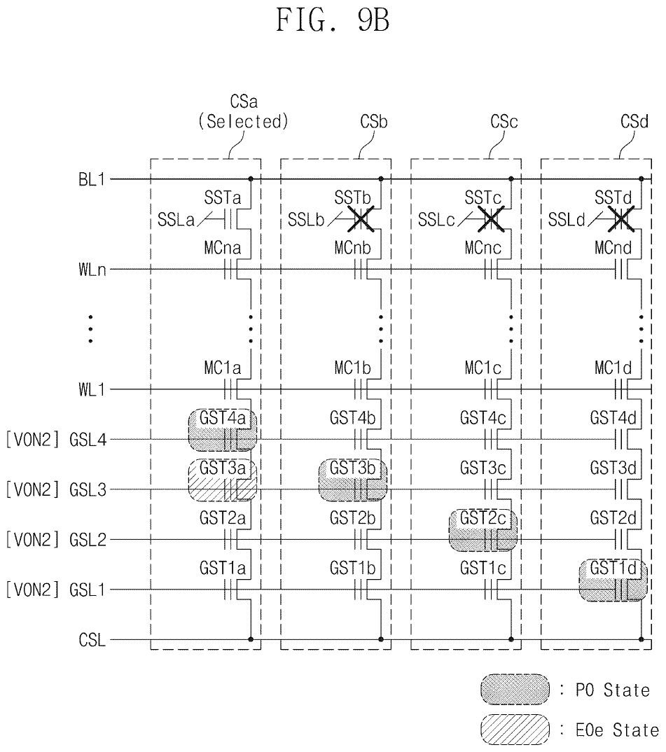

FIGS. 9A and 9B are diagrams for describing the special read operation in operation S130 of FIG. 7. Referring to FIGS. 1, 6A, 7, 9A, and 9B, the memory device 120 may perform the special read operation under control of the controller 110. For example, it is assumed that the plurality of cell strings CSa, CSb, CSc, and CSd have the coded GSL structure illustrated in FIG. 6A and the a-th cell string CSa is a selected cell string for the special read operation.

When the UECC occurs in association with the user data read through the normal read operation, the controller 110 may transmit a command for the special read operation and an address to the memory device 120. The memory device 120 may perform the special read operation in response to the command and the address.

For example, as illustrated in FIG. 9A, the memory device 120 may perform the special read operation during a second time period T2. During the special read operation, the memory device 120 may apply the on-voltage VON to the a-th string selection line SSLa corresponding to the a-th cell string CSa being the selected cell string and may apply the off-voltage VOFF to the b-th, c-th, and d-th cell strings CSb, CSc, and CSd being unselected cell strings. In some implementations, the on-voltage VON may be a high voltage sufficient to turn on the string selection transistor SSTa, and the off-voltage VOFF may be a low voltage sufficient to turn off the string selection transistors SSTb, SSTc, and SSTd.

During the special read operation, the memory device 120 may apply the read voltage VRD to a selected word line and may apply the non-selection read voltage VREAD to unselected word lines. The read voltage VRD may be a voltage for distinguishing program states of memory cells, and the non-selection read voltage VREAD may be a high voltage sufficient to turn on memory cells regardless of the program states of the memory cells.

During the special read operation, the memory device 120 may apply the second on-voltage VON2 to all the ground selection lines GSL1 to GSL4 regardless of the selected cell string. In this case, all the ground selection transistors of cell strings may be turned on by the second on-voltages VON2 of all the ground selection lines GSL1 to GSL4. In this case, the user data stored in a memory cell may be normally read regardless of the change in the threshold voltage of the ground selection transistor.

For example, as illustrated in FIG. 9B, when the second on-voltage VON2 is applied to all the ground selection lines GSL1 to GSL4, all the ground selection transistors GST1a to GST4d may be turned on regardless of the threshold voltages of the ground selection transistors GST1a to GST4d. In particular, unlike the normal read operation, even though the ground selection transistor GST3a has the 0-th error erase state E0e, the ground selection transistor GST3a may be turned on. In this case, the a-th cell string CSa being the selected cell string may be electrically connected to the common source line CSL, and thus, the user data stored in a memory cell may be normally read.

In some implementations, the description is given as during the special read operation, the memory device 120 applies the second on-voltage VON2 to all the ground selection lines GSL1 to GSL4 regardless of the selected cell string, but the present disclosure is not limited thereto. For example, during the special read operation, the memory device 120 may apply a voltage higher than the second on-voltage VON2 to all the ground selection lines GSL1 to GSL4 to turn on all the ground selection transistors GST1a to GST4d.

In some implementations, in the special read operation, as all the ground selection transistors are turned on, the unselected cell strings CSb, CSc, and CSd may also be electrically connected to the common source line CSL. However, because the string selection transistors SSTb, SSTc, and SSTd of the unselected cell strings CSb, CSc, and CSd are turned off by the off-voltage VOFF of the string selection lines SSLb, SSlc, and SSLd, the string selection transistors SSTb, SSTc, and SSTd may not be connected to the bit line BL. Accordingly, because the voltage of the bit line does not fluctuate due to the unselected cell strings SSLb, SSlc, and SSLd, the voltage of the bit line BL fluctuates only due to the selected cell string (i.e., CSa). This means that the user data are normally read from the selected word line or the selected memory cell.

In some implementations, in the special read operation, as all the ground selection transistors are turned on, all the cell strings are electrically connected to the common source line CSL. In this case, a time necessary to set up the word line WL to a target level may become long compared to the normal read operation. Accordingly, an execution time of the special read operation may be longer than an execution time of the normal read operation. That is, the time T2 for the special read operation is longer than the time T1 for the normal read operation.

As described above, the controller 110 may perform the normal read operation on the memory device 120 to read the user data. When the UECC occurs in association with the data read by the normal read operation, the controller 110 may perform the special read operation on the memory device 120 to read the user data. In this case, the issue that the user data are not normally read due to the change in the threshold voltages of the ground selection transistors GST may be solved. Accordingly, the reliability of the storage device 100 may be improved. Also, when the UECC occurs in association with the user data read through the normal read operation, because the special read operation is performed, the performance may be reduced due to the long time of the special read operation.

FIG. 10 is a flowchart illustrating the GST-care operation in operation S150 of FIG. 7. In some implementations, the case where the UECC occurs in association with the user data read through the normal read operation and an error of the user data read through the special read operation is corrected may mean that threshold voltages of ground selection transistors of the memory device 120 change.

In some implementations of the present disclosure, the storage device 100 may adjust threshold voltages of ground selection transistors to a target state in the above condition (i.e., a condition that an error of the user data read through the special read operation is corrected, in the UECC situation).

Referring to FIGS. 1, 7, and 10, in operation S150, the controller 110 may perform the GST-care operation. The GST-care operation may refer to an operation of adjusting threshold voltages of ground selection transistors to a target state and may include operation S151-1 to operation S151-5 as illustrated in FIG. 10.

In operation S151-1, the controller 110 may perform a threshold voltage check operation on ground selection transistors of the memory device 120. For example, in association with the ground selection transistors of the memory device 120, the controller 110 may detect a lower limit level of the 0-th program state P0 and an upper limit level of the 0-th erase state E0.

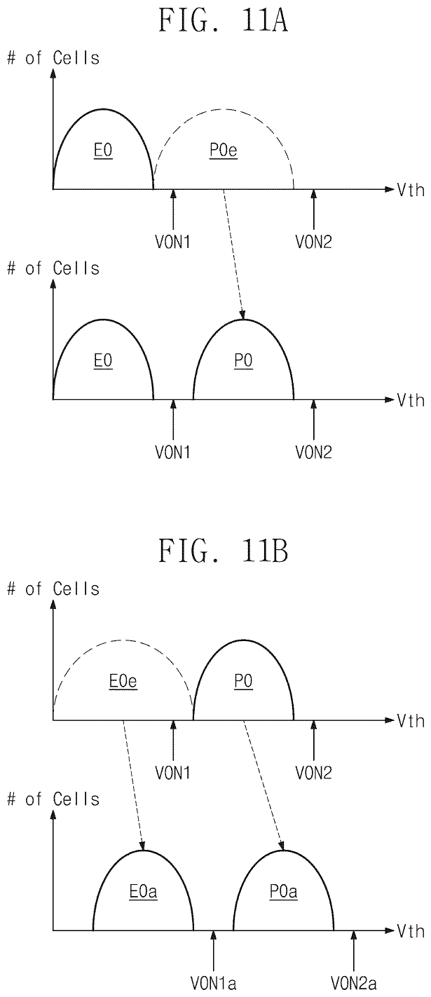

In operation S151-2, the controller 110 may perform a GST-repair operation based on a result of the threshold voltage check operation. For example, when the lower limit level of the 0-th program state P0 of the ground selection transistors of the memory device 120 is lower than a lower limit reference level, the controller 110 may perform the program operation or the soft program operation on the ground selection transistors of the 0-th program state P0 such that the lower limit level of the ground selection transistors of the 0-th program state P0 increases. Alternatively, when the upper limit level of the 0-th erase state E0 of the ground selection transistors of the memory device 120 is higher than an upper limit reference level, the controller 110 may perform the program operation or the soft program operation on the ground selection transistors such that the threshold voltages of the ground selection transistors are raised. The GST-repair operation will be described in detail with reference to FIGS. 11A and 11B.

In operation S151-3, the controller 110 may perform the normal read operation on the memory device 120. For example, the controller 110 may read the user data by performing the normal read operation on a memory block experiencing the GST-repair operation.

In operation S151-4, the controller 110 may determine whether the UECC occurs in association with the user data. For example, the controller 110 may determine the error correction operation on the user data read in operation S151-3. In this case, when the error correction operation of the user data is successful (i.e., when the user data are free from an error or an error of the user data is corrected), it may be determined that the threshold voltages of the ground selection transistors are set to the target level or the target state by the GST-repair operation. In this case, the controller 110 may terminate the GST-care operation.

In contrast, when the error correction operation of the user data fails (i.e., when an error of the user data is not corrected), it may be determined that the threshold voltages of the ground selection transistors are not set to the target level or the target state or any other defect is present in the memory block. In this case, in operation S151-5, the controller 110 may process the memory block as a run-time bad block (RTBB).

As described above, as the threshold voltages of the ground selection transistors are again set through the GST-care operation, the following normal read operation may be normally performed.

FIGS. 11A and 11B are diagrams for describing the GST-repair operation in operation S151-2 of FIG. 10. Referring to FIGS. 1, 10, 11A, and 11B, ground selection transistors of the memory device 120 may have the 0-th erase state E0 or the 0-th program state P0. Threshold voltages of the ground selection transistors may change due to various factors.

For example, as illustrated in FIG. 11A, as the threshold voltages of the ground selection transistors GST decrease, the ground selection transistors GST may have the 0-th error program state P0e. In this case, some of ground selection transistors of the 0-th error program state P0e may be turned on by the first on-voltage VON1, thereby causing the electrical connection of unselected cell strings with the common source line CSL. This may mean that the normal read operation is not normally performed.

To solve the above issue, the controller 110 may perform the program operation or the soft program operation on the ground selection transistors of the 0-th error program state P0e such that the ground selection transistors of the 0-th error program state P0e have the 0-th program state P0. In this case, the ground selection transistors GST may have the 0-th erase state E0 or the 0-th program state P0 and thus may be turned on/turned off through the first on-voltage VON1 and the second on-voltage VON2.

In some implementations, because states (i.e., E0 and P0) of the ground selection transistors GST form a given pattern, the memory device 120 may perform the program operation or the soft program operation on the ground selection transistors GST based on the given pattern.

Alternatively, as illustrated in FIG. 11B, as the threshold voltages of the ground selection transistors GST increase, the ground selection transistors GST may have the 0-th error erase state E0e. In this case, some of ground selection transistors of the 0-th error erase state E0e may be turned off by the first on-voltage VON1, thereby causing the electrical disconnection of the selected cell string from the common source line CSL. This may mean that the normal read operation is not normally performed.

To solve the above issue, the controller 110 may perform the program operation or the soft program operation on the ground selection transistors GST such that the ground selection transistors GST have a 0a-th erase state E0a or a 0a-th program state P0a. In some implementations, through the above program operation or the above soft program operation, ground selection transistors of the 0-th error erase state E0e may have the 0a-th erase state E0a, and ground selection transistors of the 0-th error program state P0e may have the 0a-th program state P0a.

In some implementations, the upper limit level and the lower limit level of the 0a-th erase state E0a may be different from the upper limit level and the lower limit level of the 0-th erase state E0, and the upper limit level and the lower limit level of the 0a-th program state P0a may be different from the upper limit level and the lower limit level of the 0-th program state P0. Accordingly, on-voltages for distinguishing the 0a-th erase state E0a and the 0a-th program state P0a may be again set to a 1a-th on-voltage VON1a and a 2a-th on-voltage VON2a. In some implementations, the 1a-th on-voltage VON1a may be higher than or equal to the first on-voltage VON1, and the 2a-th on-voltage VON2a may be higher than or equal to the second on-voltage VON2.

As described above, the controller 110 may perform the threshold voltage check operation on the ground selection transistors of the memory device 120 and may adjust or control threshold voltages of the ground selection transistors based on a result of the threshold voltage check operation.

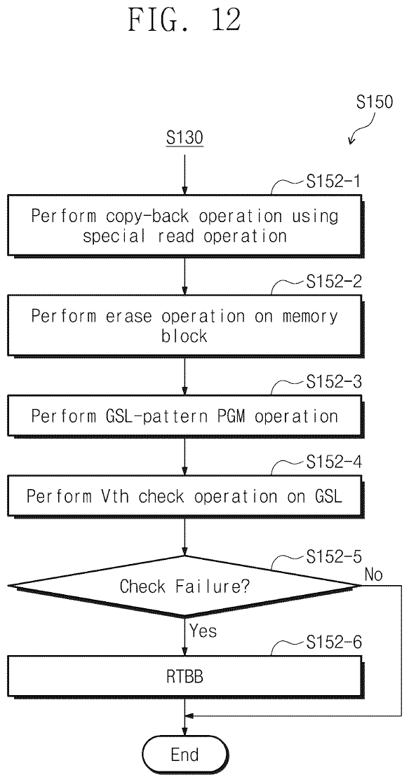

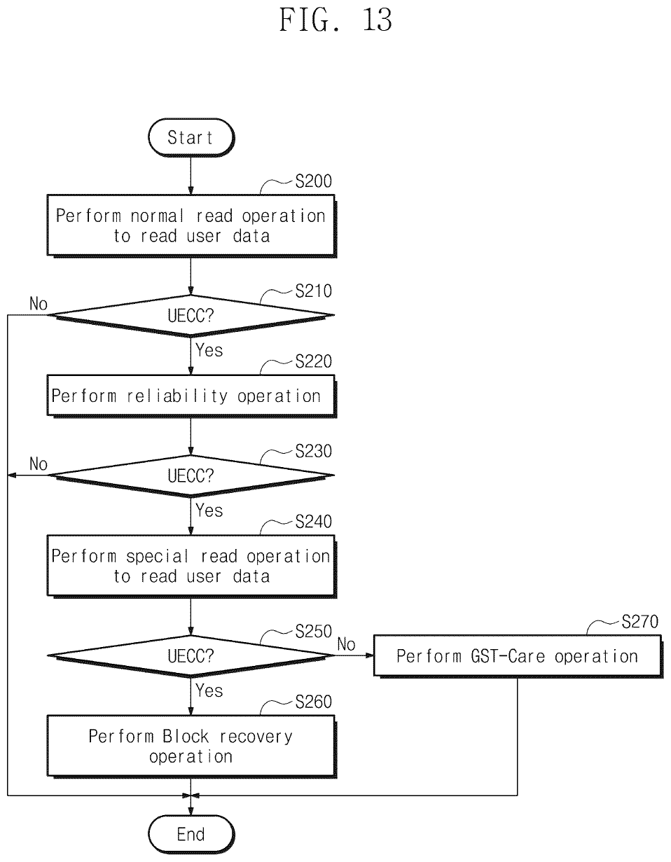

FIG. 12 is a flowchart illustrating the GST-care operation in operation S150 of FIG. 7. In some implementations, the case where the UECC occurs in association with the user data read through the normal read operation and an error of the user data read through the special read operation fails to be corrected may mean that threshold voltages of ground selection transistors of the memory device 120 change. In this case, a GST-care operation S150 may be performed (referring to FIG. 7).

Referring to FIGS. 1, 7, and 12, in operation S150, the controller 110 may perform the GST-care operation. The GST-care operation may refer to an operation of adjusting threshold voltages of ground selection transistors to a target state and may include operation S152-1 to operation S152-6 as illustrated in FIG. 12. In operation S152-1, the controller 110 may perform the copyback operation on the memory device 120 by using the special read operation. In some implementations, the copyback operation may refer to an operation of moving the user data stored in a source memory block of the memory device 120 to any other memory block, that is, a target memory block. For example, under control of the controller 110, the memory device 120 may read the user data stored in the source memory block. In this case, the read user data may be temporarily stored in the page buffer circuit 123. The memory device 120 may program the temporarily stored user data into any other memory block, that is, a target memory block. The memory device 120 may repeatedly perform the above operations (the read operation and the program operation) to move or copy all the user data stored in the source memory block to any other memory block, that is, a target memory block. In some implementations, the memory device 120 may perform the read operation belonging to the above copyback operation based on the above special read operation.

In operation S152-2, the controller 110 may perform the erase operation on the memory block. For example, the memory device 120 may perform the erase operation of the memory block under control of the controller 110. In some implementations, during the erase operation of the memory block, ground selection transistors included in the memory block may also be erased together. That is, after the erase operation is completed, the ground selection transistors of the memory block may have an erase state or the 0-th erase state E0.

In operation S152-3, the controller 110 may perform a GSL-pattern program operation. For example, under control of the controller 110, the memory device 120 may perform the GSL-pattern program operation of the ground selection transistors of the memory block. Through the GSL-pattern program operation, the ground selection transistors may have the 0-th erase state E0 or the 0-th program state P0. In some implementations, to select or control cell strings individually, the 0-th erase state E0 or the 0-th program state P0 of the ground selection transistors may have a specific pattern. This is described above, and thus, additional description will be omitted to avoid redundancy.

In operation S152-4, the controller 110 may perform the threshold voltage check operation on the ground selection transistors. For example, the memory device 120 may perform the threshold voltage check operation of the ground selection transistors under control of the controller 110. This is performed to be similar to that described in operation S151-1 of FIG. 10, and thus, additional description will be omitted to avoid redundancy.

In operation S152-5, the controller 110 may determine whether a result of the threshold voltage check operation indicates a failure. For example, through the threshold voltage check operation, the controller 110 may check the upper limit level of the 0-th erase state E0 or the lower limit level of the 0-th program state P0. When the upper limit level of the 0-th erase state E0 is higher than the first on-voltage VON1 or the lower limit level of the 0-th program state P0 is lower than the first on-voltage VON1, as described above, the normal read operation may not be performed normally. In this case, the controller 110 may determine whether a result of the threshold voltage check operation indicates a failure.

When the result of the threshold voltage check operation indicates a failure, in operation S152-6, the controller 110 may process the memory block as a run-time bad block (RTBB).

As described above, when the normal read operation is not normally performed due to the change in the threshold voltages of the ground selection transistors (i.e., when the UECC occurs in the normal read operation and an error is corrected in the special read operation), the controller 110 may perform the GST-care operation on the ground selection transistors of the memory device 120. Accordingly, the ground selection transistors of the memory device 120 may be turned on/turned off as intended, and a plurality of cell strings may be individually controlled.

In some implementations, the above operations (i.e., the GST-care operation) may be performed in units of memory block.

FIG. 13 is a flowchart illustrating an operation of a storage device of FIG. 1. For convenience, the description will be given as an operation according to the flowchart of FIG. 13 is performed by the controller 110 included in the storage device 100.

Referring to FIGS. 1 and 13, in operation S200, the controller 110 may perform the normal read operation on the memory device 120 to read the user data. In operation S210, the controller 110 may determine whether the UECC occurs in association with the user data. Operation S200 and operation S210 are similar to operation S100 and operation S110 of FIG. 7, and thus, additional description will be omitted to avoid redundancy.

When it is determined that the UECC occurs in association with the user data, in operation S220, the controller 110 may perform the reliability operation. For example, to correct an error of the user data, the controller 110 may sequentially perform various reliability operations on the memory device 120, such as a valley search operation, a predetermined table (PDT) read operation, and a soft decision decoding operation.

In operation S230, the controller 110 may determine whether the UECC occurs in association with the user data read through the reliability operation. For example, the controller 110 may determine the error correction operation for each of various reliability operations. When an error is corrected in a current reliability operation, the controller 110 may terminate the remaining reliability operation(s) other than the current reliability operation. In contrast, when the UECC occurs in all the reliability operations, the controller 110 may perform operation S240 to operation S270. Operation S240 to operation S270 are similar to operation S120 to operation S150 of FIG. 7, and thus, additional description will be omitted to avoid redundancy.

As described above, according to an implementation of the present disclosure, the storage device 100 may perform various reliability operations for correcting an error of the user data. Also, the storage device 100 may perform the special read operation to correct or detect an error of the user data due to the change in the threshold voltages of the ground selection transistors GST of the memory device 120. Accordingly, the reliability of the memory device 100 may be improved.

An implementation in which the special read operation is performed after various reliability operations are sequentially performed is illustrated in FIG. 13, but the present disclosure is not limited thereto. For example, the special read operation may be performed between various reliability operations; when an error of the user data is corrected by the special read operation, the controller 110 may perform the GST-care operation.

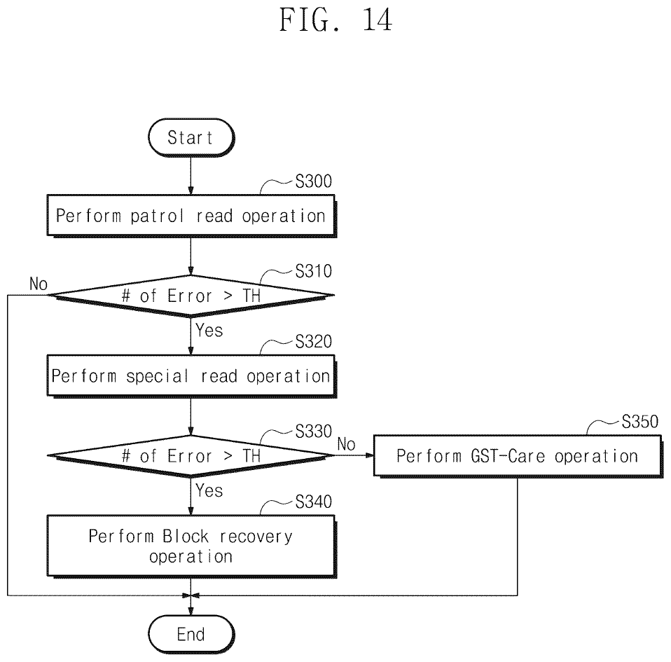

FIG. 14 is a flowchart illustrating an operation of a storage device of FIG. 1. Referring to FIGS. 1 and 14, in operation S300, the controller 110 may perform a patrol read operation. For example, during an idle time, the controller 110 may perform the patrol read operation for checking the reliability of the user data stored in the memory device 120. The patrol read operation may be performed in association with an arbitrary address of the memory device 120. In some implementations, the patrol read operation may be performed based on the normal read operation in operation S100 of FIG. 7.

In operation S310, the controller 110 may determine the number of error bits of the user data. For example, the controller 110 may perform the error correction operation on the user data read through the patrol read operation. The controller 110 may detect the number of error bits of the user data through the error correction operation. The controller 110 may determine whether the number of error bits is greater than a reference value TH. In some implementations, when the number of error bits is greater than the reference value TH, an error of the user data may not be corrected. Alternatively, the reference value TH may be smaller in magnitude than the error correction capability of the ECC engine 111. That is, even though the number of error bits is greater than the reference value TH, an error of the user data may be capable of being corrected, but the probability that the UECC occurs later due to various factors may be high.

When the number of error bits is greater than the reference value TH, in operation S320, the controller 110 may perform the special read operation. The special read operation is described above, and thus, additional description will be omitted to avoid redundancy.

In operation S330, the controller 110 may determine the number of error bits of the user data read through an all-GST-on operation. For example, the controller 110 may perform the error correction operation on the user data read through the all-GST-on operation. The controller 110 may detect the number of error bits of the user data through the error correction operation.

When the number of error bits is greater than the reference value TH, in operation S340, the controller 110 may perform the block recovery operation. As an example, the block recovery operation may refer to a recovery operation associated with a memory block where the patrol read operation or the special read operation is performed. The block recovery operation may include the copyback operation in which the user data stored in the memory block are moved to any other memory block.

When the number of error bits is not greater than the reference value TH, in operation S350, the controller 110 may perform the GST-care operation. For example, the case where the number of error bits of the user data read through the patrol read operation is greater than the reference value TH and the number of error bits of the user data read through the special read operation is not greater than the reference value TH may mean that the change in the threshold voltages of the ground selection transistors GST is made. Accordingly, the controller 110 may perform the GST-care operation for compensating for the change of the threshold voltages of the ground selection transistors GST. The GST-care operation is described above, and thus, additional description will be omitted to avoid redundancy.

As described above, according to an implementation of the present disclosure, the storage device 100 may perform the normal read operation to read the user data and may perform the error correction operation on the user data. When the UECC occurs in association with the user data, the storage device 100 may perform the special read operation to read the user data and may perform the error correction operation on the user data. Accordingly, an error which is caused due to the change in a threshold voltage of a ground selection transistor may decrease. That is, the storage device 100 may detect the change in the threshold voltages of the ground selection transistors of the memory device 120, based on whether an error of the user data stored in the memory device 120 is corrected. In some implementations, when the change in the threshold voltages of the ground selection transistors is detected, the storage device 100 may perform the GST-care operation. Accordingly, the memory device 120 with improved reliability and improved performance is provided.

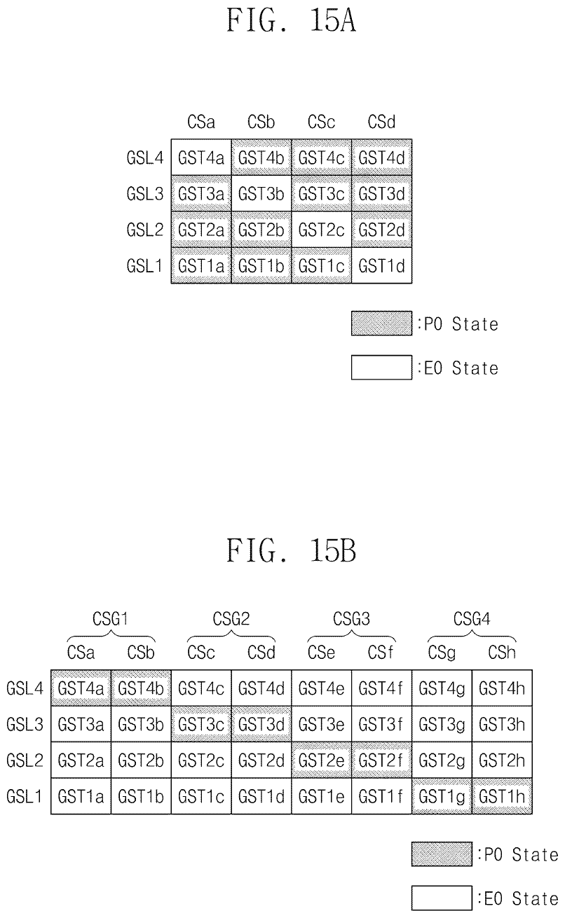

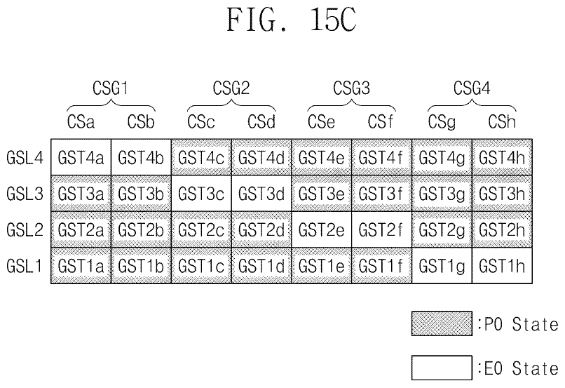

FIGS. 15A to 15C are diagrams for describing a coded GSL structure of a memory block included in a memory device of FIG. 1. In the above implementations, each cell string of a memory block includes one ground selection transistor having the 0-th program state P0. However, the present disclosure is not limited thereto.

For example, in the above implementations, the 4a-th ground selection transistor GST4a of the a-th cell string CSa, the 3b-th ground selection transistor GST3b of the b-th cell string CSb, the 2c-th ground selection transistor GST2c of the c-th cell string CSc, and the 1d-th ground selection transistor GST1d of the d-th cell string CSd may have the 0-th program state P0, and the remaining ground selection transistors GST1a, GST2a, GST3a, GST1b, GST2b, GST4b, GST1c, GST3c, GST4c, GST2d, GST3d, and GST4d may have the 0-th erase state E0.

In contrast, as illustrated in FIG. 15A, the 4a-th ground selection transistor GST4a of the a-th cell string CSa, the 3b-th ground selection transistor GST3b of the b-th cell string CSb, the 2c-th ground selection transistor GST2c of the c-th cell string CSc, and the 1d-th ground selection transistor GST1d of the d-th cell string CSd may have the 0-th erase state E0, and the remaining ground selection transistors GST1a, GST2a, GST3a, GST1b, GST2b, GST4b, GST1c, GST3c, GST4c, GST2d, GST3d, and GST4d may have the 0-th program state P0.

Under the above condition, when the a-th cell string CSa is a selected cell string, the second on-voltage VON2 may be applied to the first to third ground selection lines GSL1 to GSL3, and the first on-voltage VON1 may be applied to the fourth ground selection line GSL4. According to the above bias condition, the 1a-th, 2a-th, and 3a-th ground selection transistors GST1a, GST2a, and GST3a may be turned on by the second on-voltage VON2 of the first to third ground selection lines GSL1 to GSL3, and the 4a-th ground selection transistor GST4a may be turned on by the first on-voltage VON1 of the fourth ground selection line GSL4. Accordingly, the a-th cell string CSa may be electrically connected to the common source line CSL. Also, because the 4b-th, 4c-th, and 4d-th ground selection transistors GST4b, GST4c, and GST4d are turned off by the first on-voltage VON1 of the fourth ground selection line GSL4, the unselected cell strings CSb, CSc, and CSd may not be electrically connected to the common source line CSL.

In some implementations, in the special read operation, as the second on-voltage VON2 or a voltage higher than or equal to the second on-voltage VON2 is applied to the first to fourth ground selection lines GSL1 to GSL4, all the ground selection transistors GST1a to GST4d may be turned on.

In the above implementations, the memory block has the 4SSL-1GSL structure. However, the present disclosure is not limited thereto. For example, as illustrated in FIG. 15B, the memory block may have an 8SSL-1GSL structure. That is, eight cell strings may be respectively connected to eight string selection lines and may share the same ground selection lines. In this case, there may be a need to distinguish four cell string groups electrically. For example, a first cell string group CSG1 may include a-th and b-th cell strings CSa and CSb, a second cell string group CSG2 may include c-th and d-th cell strings CSc and CSd, a third cell string group CSG3 may include e-th and f-th cell strings CSe and CSf, and a fourth cell string group CSG4 may include a-th and b-th cell strings CSg and CSh. The cell strings CSa to CSh may be controlled (i.e., may be electrically connected to the common source line CSL) in units of cell string group.

In this case, as illustrated in FIG. 15B, a 4a-th ground selection transistor GST4a of the a-th cell string CSa, a 4b-th ground selection transistor GST4b of the b-th cell string CSb, a 3c-th ground selection transistor GST3c of the c-th cell string CSc, a 3d-th ground selection transistor GST3d of the d-th cell string CSd, a 2e-th ground selection transistor GST2e of the e-th cell string CSe, a 2f-th ground selection transistor GST2f of the f-th cell string CSf, a 1g-th ground selection transistor GST1g of the g-th cell string CSg, and a 1h-th ground selection transistor GST1h of the h-th cell string CSh may have the 0-th program state P0, and the remaining ground selection transistors may have the 0-th erase state E0. The memory device 120 may control the cell strings CSa to CSh (i.e., may electrically connect the cell strings CSa to CSh to the common source line CSL) in units of cell string group, by controlling voltages of the first to fourth ground selection lines GSL1 to GSL4.

In some implementations, the memory device 120 may perform the special read operation by applying the second on-voltage VON2 to the first to fourth ground selection lines GSL1 to GSL4.

In the implementation of FIG. 15B, the description is given as one ground selection transistor has the 0-th program state P0 in each cell string, but the present disclosure is not limited thereto. For example, as illustrated in FIG. 15C, the 4a-th ground selection transistor GST4a of the a-th cell string CSa, the 4b-th ground selection transistor GST4b of the b-th cell string CSb, the 3c-th ground selection transistor GST3c of the c-th cell string CSc, the 3d-th ground selection transistor GST3d of the d-th cell string CSd, the 2e-th ground selection transistor GST2e of the e-th cell string CSe, the 2f-th ground selection transistor GST2f of the f-th cell string CSf, the 1g-th ground selection transistor GST1g of the g-th cell string CSg, and the 1h-th ground selection transistor GST1h of the h-th cell string CSh may have the 0-th erase state E0, and the remaining ground selection transistors may have the 0-th program state P0.

The memory device 120 may control the cell strings CSa to CSh (i.e., may electrically connect the cell strings CSa to CSh to the common source line CSL) in units of cell string group, by controlling voltages of the first to fourth ground selection lines GSL1 to GSL4.

The above memory block structure (e.g., the SSL-GSL sharing structure and the coded GSL structure) of the memory device 120 is provided as an example, and the present disclosure is not limited thereto. For example, the memory block of the memory device 120 may include a plurality of cell strings sharing a ground selection line; to control the plurality of cell strings individually, ground selection transistors may have given states (i.e., E0 and P0). In this case, a structure in which a ground selection line is shared and a pattern corresponding to states of ground selection transistors may be variously changed or modified.

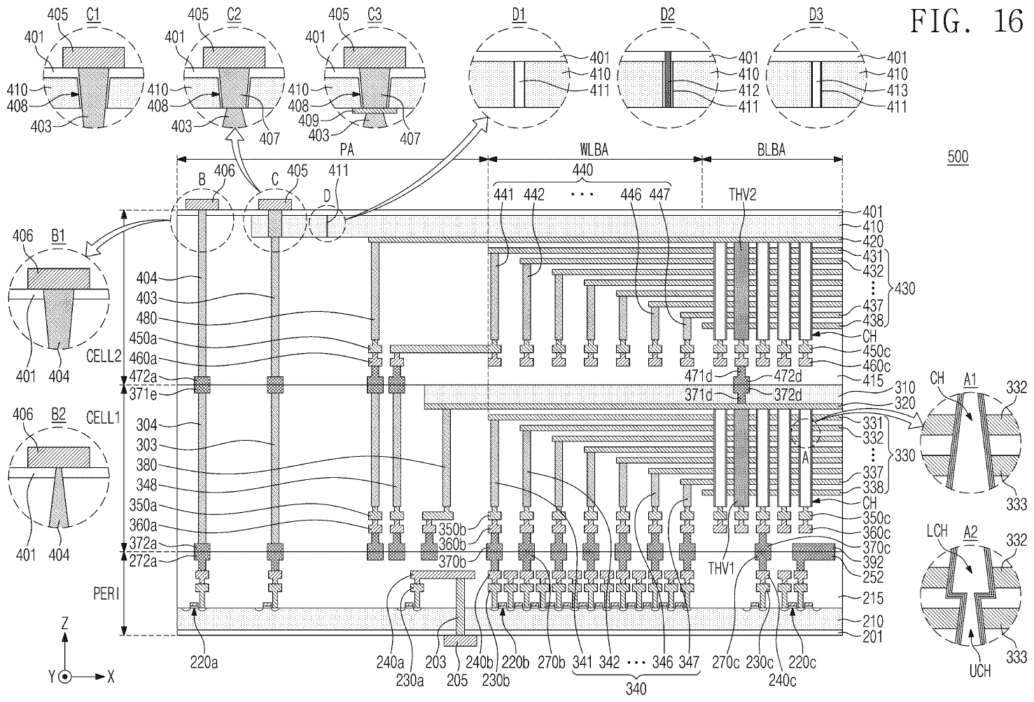

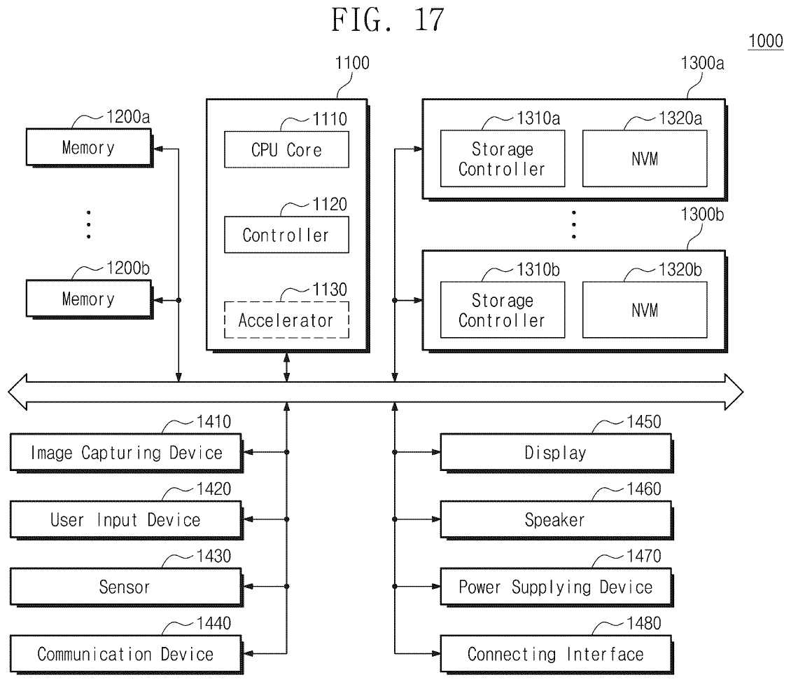

FIG. 16 is a view for describing a memory device 500 according to an implementation of the present disclosure.

Referring to FIG. 16, the memory device 500 may have a chip-to-chip (C2C) structure. Herein, in the C2C structure, after fabricating at least one upper chip including a cell region CELL and at least one lower chip including a peripheral circuit region PERI, respectively, the upper chip and the lower chip may be bonded to each other by a bonding method. As an example, the bonding method may mean a method of electrically or physically connecting a bonding metal pattern formed in the uppermost metal layer of the upper chip and a bonding metal pattern formed in the uppermost metal layer of the lower chip. For example, when the bonding metal patterns are formed of copper (Cu), the bonding method may be referred to as a “Cu—Cu bonding method”. As another example, the bonding metal patterns may also be formed of aluminum (Al) or tungsten (W).

In the case in which the memory device 500 is implemented to include two upper chips, the memory device 500 may be manufactured by separately manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by the bonding method, and the second upper chip may also be turned over and connected to the first upper chip by the bonding method. In the following description, upper portions and lower portions of the first and second upper chips are defined based on before the first upper chip and the second upper chip are turned over. That is, in FIG. 16, an upper portion of the lower chip refers to an upper portion defined based on a +Z-axis direction, and the upper portions of the first and second upper chips refer to upper portions defined based on a −Z-axis direction. However, this is illustrative, and only one of the first upper chip and the second upper chip may be turned over and connected by the bonding method.

Each of the peripheral circuit region PERI and the first and second cell regions CELL1 and CELL2 of the memory device 500 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines connecting the plurality of circuit elements 220a, 220b, and 220c may be provided in the interlayer insulating layer 215. For example, the plurality of metal lines may include first metal lines 230a, 230b, and 230c connected with the plurality of circuit elements 220a, 220b, and 220c, respectively, and second metal lines 240a, 240b, and 240c formed on the first metal lines 230a, 230b, and 230c. The plurality of metal lines may be formed of at least one of various conductive materials. For example, the first metal lines 230a, 230b, and 230c may be formed of tungsten having a relatively high electrical resistivity, and the second metal lines 240a, 240b, and 240c may be formed of copper having a relatively low electrical resistivity.

In this specification, only the first metal lines 230a, 230b, and 230c and the second metal lines 240a, 240b, and 240c are illustrated and described. However, without being limited thereto, one or more additional metal lines may be further formed on the second metal lines 240a, 240b, and 240c. In this case, the second metal lines 240a, 240b, and 240c may be formed of aluminum At least some of the additional metal lines formed on the second metal lines 240a, 240b, and 240c may be formed of copper having a lower electrical resistivity than the aluminum of the second metal lines 240a, 240b, and 240c.

The interlayer insulating layer 115 may be disposed on the first substrate 210 and may include an insulating material, such as silicon oxide or silicon nitride.

Each of the first and second cell regions CELL1 and CELL2 may include at least one memory block. The first cell region CELL1 may include a second substrate 310 and a common source line 320. A plurality of word lines 330 (331 to 338) may be stacked on the second substrate 310 in a direction (the Z-axis direction) perpendicular to an upper surface of the second substrate 310. String selection lines and a ground selection line may be disposed on and under the word lines 330, and the plurality of word lines 330 may be disposed between the string selection lines and the ground selection line. Likewise, the second cell region CELL2 may include a third substrate 410 and a common source line 420, and a plurality of word lines 430 (431 to 438) may be stacked in a direction (the Z-axis direction) perpendicular to an upper surface of the third substrate 410. The second substrate 310 and the third substrate 410 may be formed of various materials and may be, for example, silicon substrates, silicon-germanium substrates, germanium substrates, or substrates having mono-crystalline epitaxial layers grown on mono-crystalline silicon substrates. A plurality of channel structures CH may be formed in the first and second cell regions CELL1 and CELL2.

In some implementations, as illustrated in A1, the channel structure CH may be provided in the bit line bonding region BLBA and may extend in the direction perpendicular to the upper surface of the second substrate 310 to penetrate the word lines 330, the string selection lines, and the ground selection line. The channel structure CH may include a data storage layer, a channel layer, and a buried insulating layer. The channel layer may be electrically connected with a first metal line 350c and a second metal line 360c in the bit line bonding region BLBA. For example, the second metal line 360c may be a bit line and may be connected to the channel structure CH through the first metal line 350c. The bit line 360c may extend in a first direction (a Y-axis direction) parallel to the upper surface of the second substrate 310.

In some implementations, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the direction perpendicular to the upper surface of the second substrate 310 and may penetrate the common source line 320 and the lower word lines 331 and 332. The lower channel LCH may include a data storage layer, a channel layer, and a buried insulating layer and may be connected with the upper channel UCH. The upper channel UCH may penetrate the upper word lines 333 to 338. The upper channel UCH may include a data storage layer, a channel layer, and a buried insulating layer, and the channel layer of the upper channel UCH may be electrically connected with the first metal line 350c and the second metal line 360c. As the length of a channel is increased, it may be difficult to form a channel having a constant width due to process reasons. The memory device 500 according to an implementation of the present disclosure may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 332 and the word line 333 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 331 and 332 penetrated by the lower channel LCH is smaller than the number of upper word lines 333 to 338 penetrated by the upper channel UCH. However, this is illustrative, and the present disclosure is not limited thereto. In another example, the number of lower word lines penetrated by the lower channel LCH may be equal to or larger than the number of upper word lines penetrated by the upper channel UCH. Furthermore, the above-described structure and connection relationship of the channel structure CH disposed in the first cell region CELL1 may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 16, the first through-electrode THV1 may penetrate the common source line 320 and the plurality of word lines 330. However, this is illustrative, and the first through-electrode THV1 may additionally penetrate the second substrate 310. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some implementations, the first through-electrode THV1 and the second through-electrode THV2 may be electrically connected through a first through-metal pattern 372d and a second through-metal pattern 472d. The first through-metal pattern 372d may be formed on a lower side of the first upper chip including the first cell region CELL1, and the second through-metal pattern 472d may be formed on an upper side of the second upper chip including the second cell region CELL2. The first through-electrode THV1 may be electrically connected with the first metal line 350c and the second metal line 360c. A lower VIA 371d may be formed between the first through-electrode THV1 and the first through-metal pattern 372d, and an upper VIA 471d may be formed between the second through-electrode THV2 and the second through-metal pattern 472d. The first through-metal pattern 372d and the second through-metal pattern 472d may be connected by a bonding method.

Furthermore, in the bit line bonding region BLBA, an upper metal pattern 252 may be formed on the uppermost metal layer of the peripheral circuit region PERI, and an upper metal pattern 392 having the same shape as the upper metal pattern 252 may be formed on the uppermost metal layer of the first cell region CELL1. The upper metal pattern 392 of the first cell region CELL1 and the upper metal pattern 252 of the peripheral circuit region PERI may be electrically connected to each other by a bonding method. In the bit line bonding region BLBA, the bit line 360c may be electrically connected with a page buffer included in the peripheral circuit region PERI. For example, some of the circuit elements 220c of the peripheral circuit region PERI may provide a page buffer, and the bit line 360c may be electrically connected with the circuit elements 220c providing the page buffer through an upper bonding metal 370c of the first cell region CELL1 and an upper bonding metal 270c of the peripheral circuit region PERI.

Continuously referring to FIG. 16, in the word line bonding region WLBA, the word lines 330 of the first cell region CELL1 may extend in a second direction (an X-axis direction) parallel to the upper surface of the second substrate 310 and may be connected with a plurality of cell contact plugs 340 (341 to 347). A first metal line 350b and a second metal line 360b may be sequentially connected to upper portions of the cell contact plugs 340 connected to the word lines 330. In the word line bonding region WLBA, the cell contact plugs 340 may be connected with the peripheral circuit region PERI through an upper bonding metal 370b of the first cell region CELL1 and an upper bonding metal 270b of the peripheral circuit region PERI.

The cell contact plugs 340 may be electrically connected with a row decoder included in the peripheral circuit region PERI. For example, some of the circuit elements 220b of the peripheral circuit region PERI may provide a row decoder, and the cell contact plugs 340 may be electrically connected with the circuit elements 220b providing the row decoder through the upper bonding metal 370b of the first cell region CELL1 and the upper bonding metal 270b of the peripheral circuit region PERI. In some implementations, an operating voltage of the circuit elements 220b that provide the row decoder may differ from an operating voltage of the circuit elements 220c that provide the page buffer. For example, the operating voltage of the circuit elements 220c that provide the page buffer may be greater than the operating voltage of the circuit elements 220b that provide the row decoder.

Likewise, in the word line bonding region WLBA, the word lines 430 of the second cell region CELL2 may extend in the second direction (the X-axis direction) parallel to the upper surface of the third substrate 410 and may be connected with a plurality of cell contact plugs 440 (441 to 447). The cell contact plugs 440 may be connected with the peripheral circuit region PERI through an upper metal pattern of the second cell region CELL2, a lower metal pattern and an upper metal pattern of the first cell region CELL1, and a cell contact plug 348.

In the word line bonding region WLBA, the upper bonding metal 370b may be formed in the first cell region CELL1, and the upper bonding metal 270b may be formed in the peripheral circuit region PERI. The upper bonding metal 370b of the first cell region CELL1 and the upper bonding metal 270b of the peripheral circuit region PERI may be electrically connected to each other by a bonding method. The upper bonding metal 370b and the upper bonding metal 270b may be formed of aluminum, copper, or tungsten.

In the external pad bonding region PA, a lower metal pattern 371e may be formed on a lower portion of the first cell region CELL1, and an upper metal pattern 472a may be formed on an upper portion of the second cell region CELL2. The lower metal pattern 371e of the first cell region CELL1 and the upper metal pattern 472a of the second cell region CELL2 may be connected by a bonding method in the external pad bonding region PA. Likewise, an upper metal pattern 372a may be formed on an upper portion of the first cell region CELL1, and an upper metal pattern 272a may be formed on an upper portion of the peripheral circuit region PERI. The upper metal pattern 372a of the first cell region CELL1 and the upper metal pattern 272a of the peripheral circuit region PERI may be connected to each other by a bonding method.

Common source line contact plugs 380 and 480 may be disposed in the external pad bonding region PA. The common source line contact plugs 380 and 480 may be formed of a conductive material, such as metal, a metal compound, or doped poly-silicon. The common source line contact plug 380 of the first cell region CELL1 may be electrically connected with the common source line 320, and the common source line contact plug 480 of the second cell region CELL2 may be electrically connected with the common source line 420. A first metal line 350a and a second metal line 360a may be sequentially stacked on an upper portion of the common source line contact plug 380 of the first cell region CELL1, and a first metal line 450a and a second metal line 460a may be sequentially stacked on an upper portion of the common source line contact plug 480 of the second cell region CELL2.

Input/output pads 205, 405, and 406 may be disposed in the external pad bonding region PA. Referring to FIG. 16, a lower insulating layer 201 may cover a lower surface of the first substrate 210, and the first input/output pad 205 may be formed on the lower insulating layer 201. The first input/output pad 205 may be connected with at least one of the plurality of circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 and may electrically isolate the first input/output contact plug 203 from the first substrate 210.

An upper insulating layer 401 may be formed on the third substrate 410 to cover the upper surface of the third substrate 410. The second input/output pad 405 and/or the third input/output pad 406 may be disposed on the upper insulating layer 401. The second input/output pad 405 may be connected with at least one of the plurality of circuit elements 220a disposed in the peripheral circuit region PERI through second input/output contact plugs 403 and 303, and the third input/output pad 406 may be connected with at least one of the plurality of circuit elements 220a disposed in the peripheral circuit region PERI through third input/output contact plugs 404 and 304.

In some implementations, the third substrate 410 may not be disposed in the regions in which the input/output contact plugs are disposed. For example, as illustrated in B, the third input/output contact plug 404 may be separated from the third substrate 410 in a direction parallel to the upper surface of the third substrate 410, may penetrate an interlayer insulating layer 415 of the second cell region CELL2, and may be connected to the third input/output pad 406. In this case, the third input/output contact plug 404 may be formed through various processes.

For example, as illustrated in B1, the third input/output contact plug 404 may extend in the third direction (the Z-axis direction) and may have an increasing diameter toward the upper insulating layer 401. That is, while the channel structure CH described with reference to A1 has a decreasing diameter toward the upper insulating layer 401, the third input/output contact plug 404 may have an increasing diameter toward the upper insulating layer 401. For example, the third input/output contact plug 404 may be formed after the second cell region CELL2 and the first cell region CELL1 are coupled by a bonding method.

For example, as illustrated in B2, the third input/output contact plug 404 may extend in the third direction (the Z-axis direction) and may have a decreasing diameter toward the upper insulating layer 401. That is, likewise to the channel structure CH, the third input/output contact plug 404 may have a decreasing diameter toward the upper insulating layer 401. For example, the third input/output contact plug 404 may be formed together with the cell contact plugs 440 before the second cell region CELL2 and the first cell region CELL1 are coupled by a bonding method.

In some implementations, an input/output contact plug may be disposed to overlap the third substrate 410. For example, as illustrated in C, the second input/output contact plug 403 may be formed through the interlayer insulating layer 415 of the second cell region CELL2 in the third direction (the Z-axis direction) and may be electrically connected to the second input/output pad 405 through the third substrate 410. In this case, a connection structure of the second input/output contact plug 403 and the second input/output pad 405 may be implemented in various ways.

For example, as illustrated in C1, an opening 408 may be formed through the third substrate 410, and the second input/output contact plug 403 may be directly connected to the second input/output pad 405 through the opening 408 formed in the third substrate 410. In this case, as illustrated in C1, the second input/output contact plug 403 may have an increasing diameter toward the second input/output pad 405. However, this is illustrative, and the second input/output contact plug 403 may have a decreasing diameter toward the second input/output pad 405.

For example, as illustrated in C2, the opening 408 may be formed through the third substrate 410, and a contact 407 may be formed in the opening 408. One end portion of the contact 407 may be connected to the second input/output pad 405, and an opposite end portion of the contact 407 may be connected to the second input/output contact plug 403. Accordingly, the second input/output contact plug 403 may be electrically connected to the second input/output pad 405 through the contact 407 in the opening 408. In this case, as illustrated in C2, the contact 407 may have an increasing diameter toward the second input/output pad 405, and the second input/output contact plug 403 may have a decreasing diameter toward the second input/output pad 405. For example, the third input/output contact plug 403 may be formed together with the cell contact plugs 440 before the second cell region CELL2 and the first cell region CELL1 are coupled by a bonding method, and the contact 407 may be formed after the second cell region CELL2 and the first cell region CELL1 are coupled by the bonding method.

For example, as illustrated in C3, a stopper 409 may be additionally formed on an upper surface of the opening 408 of the third substrate 410. The stopper 409 may be a metal line formed on the same layer as the common source line 420. However, this is illustrative, and the stopper 409 may be a metal line formed on the same layer as at least one of the word lines 430. The second input/output contact plug 403 may be electrically connected to the second input/output pad 405 through the contact 407 and the stopper 409.

Meanwhile, similarly to the second and third input/output contact plugs 403 and 404 of the second cell region CELL2, the second and third input/output contact plugs 303 and 304 of the first cell region CELL1 may have a decreasing diameter toward the lower metal pattern 371e, or may have an increasing diameter toward the lower metal pattern 371e.

Meanwhile, in some implementations, a slit 411 may be formed in the third substrate 410. For example, the slit 411 may be formed at any position in the external pad bonding region PA. For example, as illustrated in D, the slit 411 may be located between the second input/output pad 405 and the cell contact plugs 440 when viewed on a plane. However, this is illustrative, and the slit 411 may be formed such that the second input/output pad 405 is located between the slit 411 and the cell contact plugs 440 when viewed on the plane.

For example, as illustrated in D1, the slit 411 may be formed through the third substrate 410. For example, the slit 411 may be used to prevent the third substrate 410 from being finely cracked when the opening 408 is formed. However, this is illustrative, and the slit 411 may be formed to have a depth ranging from about 60% to about 70% of the thickness of the third substrate 410.

For example, as illustrated in D2, a conductive material 412 may be formed in the slit 411. For example, the conductive material 412 may be used to discharge a leakage current generated while circuit elements in the external pad bonding region PA are driven. In this case, the conductive material 412 may be connected to an external ground line.

For example, as illustrated in D3, an insulating material 413 may be formed in the slit 411. For example, the insulating material 413 may be formed to electrically isolate the second input/output pad 405 and the second input/output contact plug 403 disposed in the external pad bonding region PA from the word line bonding region WLBA. An influence of a voltage provided through the second input/output pad 405 on a metal layer disposed on the third substrate 410 in the word line bonding region WLBA may be interrupted by forming the insulating material 413 in the slit 411.

Meanwhile, in some implementations, the first to third input/output pads 205, 405, and 406 may be selectively formed. For example, the memory device 500 may be implemented to include only the first input/output pad 205 disposed on the first substrate 201, only the second input/output pad 405 disposed on the third substrate 410, or only the third input/output pad 406 disposed on the upper insulating layer 401.

Meanwhile, in some implementations, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the peripheral circuit region PERI and the first cell region CELL1 are bonded to each other, and an insulating layer for covering an upper surface of the common source line 320 or a conductive layer for connection may be formed. Similarly, the third substrate 410 of the second cell region CELL2 may be removed before or after the first cell region CELL1 and the second cell region CELL2 are bonded to each other, and the upper insulating layer 401 for covering an upper surface of the common source line 420 or a conductive layer for connection may be formed.

In some implementations, the memory device 500 of FIG. 16 may be the memory device 100 described with reference to FIGS. 1 to 15. As an example, the cell region (e.g., CELL1 or CELL2) of the memory device 500 may include a plurality of ground selection lines, and the plurality of ground selection lines may be connected to the plurality of ground selection transistors GST. In this case, the plurality of ground selection transistors GST may have a coding pattern (i.e., having different threshold voltages) for individually controlling cell strings. Under control of the controller, the memory device 500 may perform the read operation (i.e., the special read operation) in which all the ground selection transistors GST are turned on. Under control of the controller, the memory device 500 may control threshold voltages of the plurality of ground selection transistors GST.

FIG. 17 is a diagram of a system 1000 to which a storage device is applied, according to an implementation. The system 1000 of FIG. 17 may basically be a mobile system, such as a portable communication terminal (e.g., a mobile phone), a smartphone, a tablet personal computer (PC), a wearable device, a healthcare device, or an Internet of things (IOT) device. However, the system 1000 of FIG. 17 is not necessarily limited to the mobile system and may be a PC, a laptop computer, a server, a media player, or an automotive device (e.g., a navigation device).

Referring to FIG. 17, the system 1000 may include a main processor 100, memories (e.g., 200a and 200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some implementations, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVM (Non-Volatile Memory) s 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some implementations, each of the storage devices 1300a and 1300b may be the storage device 100 described with reference to FIGS. 1 to 15 or may operate based on the operation method described with reference to FIGS. 1 to 15.

According to the present disclosure, a storage device with improved reliability and improved performance, an operation method of the storage device, and an operation method of a memory device are provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. An operation method of a storage device, wherein the storage device includes a memory device and a controller configured to control the memory device, the method comprising:
performing a normal read operation on a first memory block of the memory device to read first user data;
performing an error correction operation on the first user data; and
when an error of the first user data fails to be corrected responsive to the error correction operation on the first user data, performing a special read operation on the first memory block to read second user data,
wherein the first memory block comprises a plurality of cell strings,
wherein the plurality of cell strings share a plurality of ground selection lines,
wherein, in the normal read operation, the memory device applies a first voltage to at least one ground selection line of the plurality of ground selection lines and applies a second voltage higher than the first voltage to remaining ground selection lines of the plurality of ground selection lines, and
wherein, in the special read operation, the memory device applies the second voltage or a third voltage higher than the second voltage to the plurality of ground selection lines.

2. The operation method of claim 1, wherein the normal read operation is performed during a first time period, and the special read operation is performed during a second time period that is longer than or equal to the first time period.

3. The operation method of claim 1, wherein each of the plurality of cell strings comprises a plurality of ground selection transistors, and
wherein the plurality of ground selection transistors are respectively connected to the plurality of ground selection lines.

4. The operation method of claim 3, wherein each of the plurality of ground selection transistors has a 0-th erase state or a 0-th program state,
wherein the first voltage is higher than threshold voltages of ground selection transistors having the 0-th erase state of the plurality of ground selection transistors and is lower than threshold voltages of ground selection transistors having the 0-th program state of the plurality of ground selection transistors, and
wherein the second voltage is higher than the threshold voltages of the ground selection transistors having the 0-th program state of the plurality of ground selection transistors.

5. The operation method of claim 1, wherein a first cell string and a second cell string of the plurality of cell strings are connected to a first string selection line,
wherein a third cell string and a fourth cell string of the plurality of cell strings are connected to a second string selection line,
wherein the first cell string and the third cell string are connected to a first bit line, and
wherein the second cell string and the fourth cell string are connected to a second bit line.

6. The operation method of claim 5, wherein, in each of the normal read operation and the special read operation, the memory device applies an on-voltage to the first string selection line and applies an off-voltage to the second string selection line.

7. The operation method of claim 5, wherein the plurality of cell strings share a plurality of word lines, and
the first user data and the second user data are associated with data stored in memory cells connected to a selected word line of the plurality of word lines.

8. The operation method of claim 1, further comprising:
performing an error correction operation on the second user data; and
when an error of the second user data fails to be corrected responsive to the error correction operation on the second user data, performing a block recovery operation or processing the first memory block as a run-time bad block.

9. The operation method of claim 1, further comprising:
Performing an error correction operation on the second user data; and
when an error of the second user data fails to be corrected responsive to the error correction operation on the second user data, performing a reliability operation on the first memory block,
wherein the reliability operation comprises soft decision decoding.

10. The operation method of claim 1, further comprising:
performing an error correction operation on the second user data; and
when an error of the second user data is corrected responsive to the error correction operation on the second user data, performing a ground selection transistor (GST)-care operation such that a threshold voltage of at least one of a plurality of ground selection transistors of the first memory block is adjusted.

11. The operation method of claim 10, wherein the GST-care operation comprises:
performing a copyback operation such that data stored in the first memory block are moved to a second memory block;
erasing the first memory block; and
programming ground selection transistors of the first memory block to form a predetermined pattern.

12. The operation method of claim 10, wherein the GST-care operation comprises:
performing a threshold voltage check operation on the plurality of ground selection transistors of the first memory block; and
performing a program operation on the at least one of the plurality of ground selection transistors based on a result of the threshold voltage check operation.

13. A storage device comprising:
a memory device comprising a first memory block; and
a controller configured to perform a normal read operation on the first memory block to read first user data,
wherein the controller is configured to perform a special read operation on the first memory block to read second user data responsive to an error correction operation on the first user data failing to correct an error of the first user data,
wherein the first memory block comprises a plurality of cell strings sharing a plurality of ground selection lines,
wherein, in the normal read operation, the memory device is configured to apply a first voltage to at least one ground selection line of the plurality of ground selection lines and apply a second voltage higher than the first voltage to remaining ground selection lines of the plurality of ground selection lines, and
wherein, in the special read operation, the memory device is configured to apply the second voltage or a third voltage higher than the second voltage to the plurality of ground selection lines.

14. The storage device of claim 13, wherein the memory device is configured to perform the normal read operation during a first time period and perform the special read operation during a second time period that is longer than or equal to the first time period.

15. The storage device of claim 13, wherein the first memory block is configured to store the first user data and the second user data in the same memory cells of the first memory block.

16. The storage device of claim 13, wherein the controller comprises an error correction code (ECC) engine configured to perform an error correction operation on at least one of the first user data or the second user data.

17. The storage device of claim 16, wherein the memory device is further configured to perform a program operation on at least one ground selection transistor of a plurality of ground selection transistors of the first memory block under control of the controller responsive to the ECC engine correcting an error of the second user data.

18. An operation method of a memory device, wherein the memory device comprises a first memory block including a plurality of cell strings sharing a plurality of ground selection lines, the method comprising:
reading first user data by performing a normal read operation on the first memory block in response to receiving a first command and a first address received from a controller;
transmitting the first user data to the controller;
reading second user data by performing a special read operation on the first memory block in response to receiving a second command and the first address from the controller; and
transmitting the second user data to the controller,
wherein, in the normal read operation, a first voltage is applied to at least one ground selection line of the plurality of ground selection lines, and a second voltage higher than the first voltage is applied to remaining ground selection lines of the plurality of ground selection lines, and
wherein, in the special read operation, the second voltage or a third voltage higher than the second voltage is applied to the plurality of ground selection lines.

19. The method of claim 18, wherein the normal read operation is performed during a first time period, and the special read operation is performed during a second time period that is longer than or equal to the first time period.

20. The method of claim 18, wherein a first cell string and a second cell string of the plurality of cell strings are connected to a first string selection line,
wherein a third cell string and a fourth cell string of the plurality of cell strings are connected to a second string selection line, and
wherein, in each of the normal read operation and the special read operation, an on-voltage is applied to the first string selection line, and an off-voltage is applied to the second string selection line.
